(19) United States
(12) Patent Application Publication
(10) Pub. No.: US 2016/0048624 A1
(43) Pub. Date: Feb. 18, 2016

(54) CIRCUIT AND LAYOUT DESIGN METHODS AND LOGIC CELLS FOR SOFT ERROR HARD INTEGRATED CIRCUITS

(71) Applicant: Klas Olof Lilja, Dublin, CA (US)

(72) Inventor: Klas Olof Lilja, Dublin, CA (US)

(21) Appl. No.: 14/666,043

(22) Filed: Mar. 23, 2015

Related U.S. Application Data
(62) Division of application No. 14/060,162, filed on Oct. 22, 2013, now abandoned.
Application No. 14/060,162 is a continuation-in-part of application No. 13/463,688, filed on May 3, 2012, now abandoned.
Application No. 13/463,688 is a continuation-in-part of application No. 12/354,655, filed on Jan. 15, 2009, now abandoned.
(60) Provisional application No. 61/011,599, filed on Jan. 17, 2008.
(60) Provisional application No. 61/011,989, filed on Jan. 22, 2008.
(60) Provisional application No. 61/068,483, filed on Mar. 7, 2008.
(60) Provisional application No. 61/123,003, filed on Apr. 5, 2008.

(51) Int. Cl. G06F 17/50; H01L 27/02

(52) U.S. Cl. CPC G06F 17/5072; H01L 27/0207; G06F 17/5081

(57) ABSTRACT

In various embodiments, an integrated circuit derived from an integrated circuit layout is disclosed. In some embodiments, the integrated circuit layout comprises a first contact area from a first logic cell and a second contact area from a second logic cell. The second contact area comprises a non-zero, non-opposing effect with respect to the first contact area. The first contact area and the second contact area comprise a first distance. When the first distance is below a predetermined threshold, the first logic cell and the second logic cell are placed along a first R-line of the circuit and a third contact area comprising an opposing effect with respect to the first contact area and the second contact area is placed between the first contact area and second contact area.

### CROSS-REFERENCE TO RELATED APPLICATIONS

This application is a divisional of U.S. patent application Ser. No. 14/060,162, filed on Oct. 22, 2013, entitled “CIRCUIT AND LAYOUT DESIGN METHODS AND LOGIC CELLS FOR SOFT ERROR HARD INTEGRATED CIRCUITS,” which is a continuation-in-part of U.S. patent application Ser. No. 13/463,688, filed on May 3, 2012, entitled “LAYOUT METHOD FOR SOFT-ERROR HARD ELECTRONICS, AND RADIATION HARDENED LOGIC CELL,” which is a continuation-in-part of U.S. patent application Ser. No. 13/692,800, filed on Dec. 3, 2012, entitled “Soft Error Hard Electronics Layout Arrangement and Logic Cells,” and claims benefits of U.S. Provisional Pat. App. Nos. 61/795,654, filed on Oct. 22, 2012, entitled “CIRCUIT AND LAYOUT DESIGN METHODS AND LOGIC CELLS FOR SOFT ERROR HARD INTEGRATED CIRCUITS” and 61/806,651, filed on Mar. 29, 2013, entitled “LAYOUTS AND LAYOUT CONSTRUCTION METHOD FOR SOFT ERROR HARD INTEGRATED CIRCUITS,” each of which is incorporated herein by reference in its entirety; U.S. patent application Ser. No. 13/463,688 is a continuation-in-part of U.S. patent application Ser. No. 12/354,655, filed on Jan. 15, 2009, entitled “LAYOUT METHOD FOR SOFT-ERROR HARD ELECTRONICS, AND RADIATION HARDENED LOGIC CELL,” which claims the benefit of U.S. Provisional Pat. App. Nos. 61/011,599, filed on Jan. 17, 2008, entitled “Layout methodology for soft-error hard electronics,” 61/011,989, filed on Jan. 22, 2008, entitled “Robust cell layout synthesis methodology for soft-error hard electronics,” 61/068,483, filed on Mar. 7, 2008, entitled “Circuit and layout for a radiation hard sequential circuit element,” and 61/123,003, filed on Apr. 5, 2008, entitled “Design technique, and layout and circuit configurations, for radiation hardening of logic circuits,” each of which is hereby incorporated by reference in its entirety; U.S. patent application Ser. No. 13/692,800 claims the benefit of U.S. Provisional Pat. Appl. No. 61/630,008, filed on Dec. 2, 2011, entitled “Soft error hard electronics layout arrangement and logic cells,” which is incorporated herein by reference in its entirety.

### GOVERNMENT SUPPORT

This invention was made with Government Support under HDTRA1-10-C-0078 and HDTRA1-11-P-0018 awarded by DTRA. The Government has certain rights in this invention.

### BACKGROUND

A radiation generated single event (soft) error (SEE) occurs when a charge generated in a semiconductor material by one or more charged particles is collected by a contact area and generates a pulse in a circuit. A contact area comprises, for example, a low resistivity region on and/or in the semiconductor substrate. A contact area is coupled to a net in the circuit. Examples of contact areas include, for example, the source and drain areas in MOSFET technology. A circuit net (or node) comprises a portion of a circuit, connected by low resistivity regions, which maintains a certain voltage value throughout the net. The voltage value of the net is referred to as the voltage state of the net. A net may be connected to one or more contact areas.

State-of-the art for layout techniques for soft-error hard design mainly consist of simple spacing and sizing, and in adding additional contacts. The problem of soft errors generated by single event transients (and single event upsets) is expected to increase drastically in ultra-deep submicron (<90 nm) technologies. Of particular significance is that logic circuits are expected to become much more sensitive to radiation generated soft-errors and possibly surpass memory as the major source of single event errors. Furthermore, the generation rate of multiple errors, multiple bit upsets (MBU), and single-event multiple upset (SEMU) increases in ultra-deep submicron technologies. This is primarily caused by the spatial distribution and pulse length of a single event transient (SET) being relatively large with respect to a higher feature integration and higher frequencies of ultra-deep submicron technologies, increasing the probability that a SET pulse is latched-in as an error or that SET pulses are generated simultaneously on several circuit nodes by one single event. The problem with increasing soft-error rates is further complicated by the escalating cost of semiconductor design and manufacturing. The high cost involved in developing and maintaining a semiconductor FAB makes it highly desirable to use standard commercial semiconductor manufacturing for applications that require a high radiation tolerance. Furthermore, the design process is also becoming very complex and expensive, and it would be highly desirable to be able to re-use standard design IP and libraries as much as possible for radhard applications.

Current radhard-by-design technology for single event errors include triplication (triple mode redundancy, TMR) or duplication (built-in soft-error resilience, BiSER) of circuits, combined with some form of voting circuitry. These techniques generate undesirable power and area overhead, and current versions of these techniques cannot handle MBUs or SEMUs. Error correction codes, ECC, for memory, which may be applied as RHBD, is more efficient than duplication/triplication and can, with additional overhead, handle multiple errors in memory circuitry. However, the application of a corresponding error correction to logic circuits is very limited and application specific, for example, requiring a selective parity check or insertion of a specialized checking circuit.

### SUMMARY

In various embodiments, an integrated circuit layout is disclosed. The integrated circuit layout comprises a first contact area from a first logic cell and a second contact area from a second logic cell. The second contact area comprises a non-zero, non-opposing effect with respect to the first contact area. The first contact area and the second contact area comprise a first distance. When the first distance is below a predetermined threshold the first logic cell and the second logic cell are placed along a first R-line of the circuit and a third contact area comprising an opposing effect with respect to the first contact area and the second contact area is placed between the first contact area and second contact area.

In various embodiments, an integrated circuit filter cell is disclosed. The integrated circuit filter cell comprises a first p-type MOSFET comprising a source coupled to a power net, a drain, and a gate coupled to an input. A second p-type MOSFET comprises a source coupled to the drain of the first p-type MOSFET, a drain coupled to an inverse output, and a gate. A third p-type MOSFET comprises a source coupled to the power net, a drain, and a gate coupled to an inverse input. A fourth p-type MOSFET comprises a source coupled to the drain of the third p-type MOSFET, a drain coupled to an output, and a gate. A first n-type MOSFET comprises a source coupled to a ground net, a drain, and a gate coupled to the input. A second n-type MOSFET comprises a source coupled to the drain of the first n-type MOSFET, a drain coupled to the inverse output, and a gate. A third n-type MOSFET comprises a source coupled to the ground net, a drain, and a gate coupled to the inverse input. A fourth n-type MOSFET comprises a source coupled to the drain of the third n-type MOSFET, a drain coupled to the output, and a gate.

In various embodiments, an integrated circuit layout is disclosed. The integrated circuit layout comprises a first p-type MOSFET comprising a source coupled to a power net of a circuit, a drain coupled to the output, and a gate coupled to the first input. A second p-type MOSFET comprises a source coupled to the power net, a drain coupled to the output, and a gate coupled to the second input. A third p-type MOSFET comprises a source coupled to the power net, a drain coupled to the output, and a gate coupled to the third input. A fourth p-type MOSFET comprises a source coupled to the power net, a drain, and a gate coupled to the first inverse input. A fifth p-type MOSFET comprises a source coupled to the drain of the fourth p-type MOSFET, a drain, and a gate coupled to the second inverse input. A sixth p-type MOSFET comprises a source coupled to the drain of the fifth p-type MOSFET, a drain coupled to the inverse output, and a gate coupled to the third inverse input.

### FIGURES

The features of the various embodiments are set forth with particularity in the appended claims. The various embodiments, however, both as to organization and methods of operation, together with advantages thereof, may best be understood by reference to the following description, taken in conjunction with the accompanying drawings as follows:

FIG. 1 illustrates one embodiment of primary opposing nodes in a latch cell.

FIG. 2 illustrates one embodiment of a principal arrangement of opposing nodes of a latch circuit.

FIG. 3 illustrates one embodiment of a basic netlist for a Dual Interlocked Cell (DICE) latch cell.

FIG. 4 illustrates one embodiment of a schematic for a DICE latch circuit used for generation of a matrix.

FIG. 5 illustrates a p-type drain of a first node (n1) and a second node (n3) comprising p-type contact areas having a strong non-opposing effect.

FIG. 6 illustrates two contact area pairs comprising a strong non-opposing effect.

FIG. 7 illustrates placement steps for the DICE latch illustrated in FIG. 1.

FIG. 8 illustrates one embodiment of a schematic for an XOR-based 1-bit adder.

FIG. 9 illustrates one embodiment of a compact principle layout placement arrangement for the 1-bit adder of FIG. 8.

FIG. 10 illustrates one embodiment of a schematic of the 1-bit adder comprising a filter cell.

FIG. 11 illustrates a principle layout placement for the 1-bit adder after insertion of the filter cell.

FIG. 12 illustrates one embodiment of a dual inverse redundant (DIR) LEAP^{R} c-element filter cell.

FIG. 13 illustrates one embodiment of a principle layout for the LEAP^{R} c-element filter cell illustrated in FIG. 12.

FIG. 14 illustrates one embodiment of internal generation of the inverse signal inputs required for the LEAP^{R} c-element filter cell of FIG. 12.

FIG. 15 illustrates one embodiment of a placement of a LEAP^{R}-INV cell used to generate inverse signals for the LEAP^{R} c-element.

FIG. 16 illustrates one embodiment of a placement of the LEAP^{R}-INV cell used to generate inverse signals for the LEAP^{R} c-element in a LEAP 1-bit adder circuit.

FIG. 17 illustrates one embodiment of a schematic for a reverse redundant logic LEAP^{R} NAND3/NOR3 gate.

FIG. 18 illustrates one embodiment of a principle layout for the reverse redundant logic LEAP^{R} NAND3/NOR3 gate of FIG. 17.

FIG. 19A illustrates one embodiment of LEAP^{R} cells arranged in the same R-direction.

FIG. 19B illustrates one embodiment of a LEAP^{R} cell arrangement comprising filters inserted between each LEAP^{R} cell.

FIG. 20 illustrates one embodiment of a SET filter insertion for a master filter-clocking latch.

FIG. 21 illustrates one embodiment of a SET filter insertion for a slave filter-clocking latch.

FIG. 22 illustrates one embodiment of an integrated SET filter for a DICE circuit comprising tri-state clocking.

FIG. 23 illustrates one embodiment of a schematic for the LEAP^{R}AOI21 gate.

FIG. 24 illustrates one embodiment of a principle layout for the LEAP^{R}AOI21 gate.

FIG. 25 illustrates one embodiment of a cell abutment of LEAP^{R}NAND cells comprising a primary-to-primary and pmos-to-pmos abutment.

FIG. 26A illustrates one embodiment of an error free abutment for the LEAP^{R}NAND cell comprising a primary-to-primary and nmos-to-pmos abutment.

FIG. 26B illustrates one embodiment of an error free abutment for the LEAP^{R}NAND cell comprising a redundant-to-redundant and nmos-to-pmos abutment.

FIGS. 27A and 27B illustrate embodiments of triple mode redundancy (TMR) inverter (INV) circuit principle layouts.

FIG. 28 illustrates one embodiment of a LEAP layout for a regular TMR INV principle layout.

FIGS. 29A and 29B illustrate embodiments of LEAP^{3R} data paths.

FIGS. 30A and 30B illustrate embodiment of LEAP inter-cell placements for the TMR LEAP^{3R} INVs illustrated in FIGS. 29A and 29B.

FIG. 31 illustrates one embodiment of a partially-LEAP compliant LEAP^{3R} cell.

FIG. 32 illustrates one embodiment of a voting latch.

FIG. 33 illustrates one embodiment of an input for the voting latch illustrated in FIG. 32.

FIG. 34 illustrates one embodiment of an input for the voting latch illustrated in FIG. 32.

### DESCRIPTION

Reference will now be made in detail to several embodiments, including embodiments showing example implementations of circuit and layout design methods and logic cells for soft error hard integrated circuits. Wherever practicable similar or like reference numbers may be used in the figures and may indicate similar or like functionality. The figures depict example embodiments of the disclosed circuits and/or methods of use for purposes of illustration only. One skilled in the art will readily recognize from the following description that alternative example embodiments of the structures and methods illustrated herein may be employed without departing from the principles described herein.

In various embodiments, the present disclosure is directed to circuits and circuit layouts for logic circuits. The disclosed logic circuits protect against soft errors (non-destructive errors) and/or greatly reduce the effects of soft errors. In some embodiments, the logic circuits and circuit layouts are used in CMOS based logic circuits (≦90 nm). The present disclosure provides a unique circuit configuration, which provides protection against single event generated soft errors.

In one embodiment, a radiation single event causes charge to be collected by a contact area, generating a pulse in the circuit. The pulse in the circuit changes the voltage of a circuit net connected to the contact area in which charge was collected. A pulse may upset, or change, a sequential element, such as, for example, a latch or a flip-flop, propagate through combinational logic, such as, for example, a set of digital logic gates, and/or be latched in as an error in the next sequential element in a circuit.

The effect of a single event on the voltage state of the net is different for different contact areas. For example, a single event can have the effect of increasing the voltage on the net or decreasing the voltage of the net depending on where the contact area affected by the single event is located in the substrate and/or how the contact area is coupled to the circuit. In various embodiments, a Layout design through Error Aware Positioning (LEAP) methodology is applied to determine an arrangement of contacts areas configured such that a single event generated pulse in the circuit is negated by an opposing element. For example, in one embodiment, two or more contact areas are arranged in an opposing arrangement such that the effect of a single event on a first contact area is negated by the effect of the single event on a second contact area. LEAP may refer to the methodology and/or integrated circuit cells which have been laid out in accordance with the methodology. In various embodiments, LEAP layouts are generated for integrated circuits, including, for example, redundant circuits and/or regular (non-redundant) circuits.

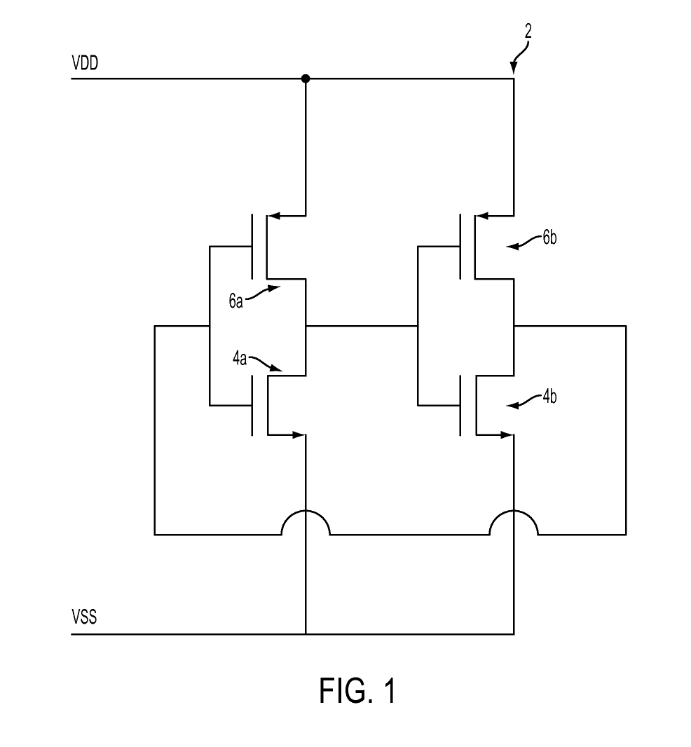

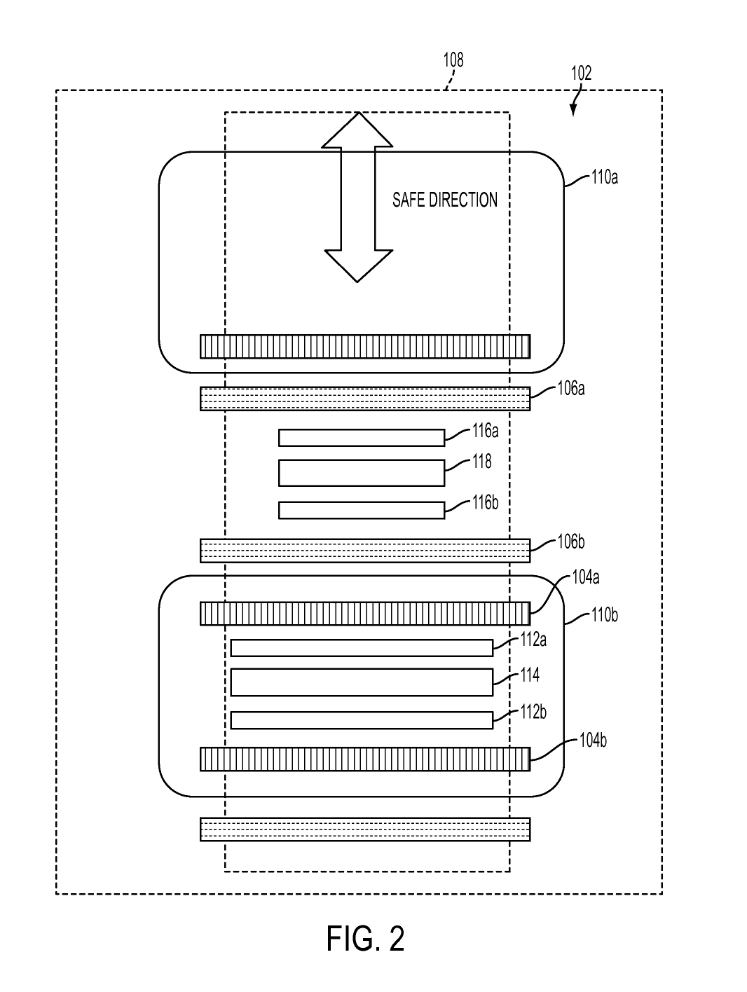

FIG. 1 illustrates one embodiment of a latch cell 2 comprising a plurality of opposing nodes. A first nmos 4a and a second nmos 4b comprise an opposing arrangement for nmos elements. A first pmos 6a and a second pmos 6b comprise an opposing arrangement for pmos elements. The first pmos 6a and the first nmos 4a comprise an nmos/pmos drain node opposing arrangement. In some embodiments, the nmos/pmos opposing arrangement is symmetrical. FIG. 2 illustrates one embodiment of a principal arrangement 102 of opposing nodes of the latch cell 2. The principal arrangement 102 comprises a PWELL substrate region 108 surrounding a plurality of NWELL contact regions 110a, 110b. The NWELL contact regions 110a, 110b comprise NWELL contacts 104a, 104b 104c, PMOS drains 112a, 112b, and a PMOS source 114. The NWELL contact regions 110a, 110b are opposed by PWELL contacts 106a, 106b comprising nmos drains 116a, 116b and an nmos source 118 disposed therebetween.

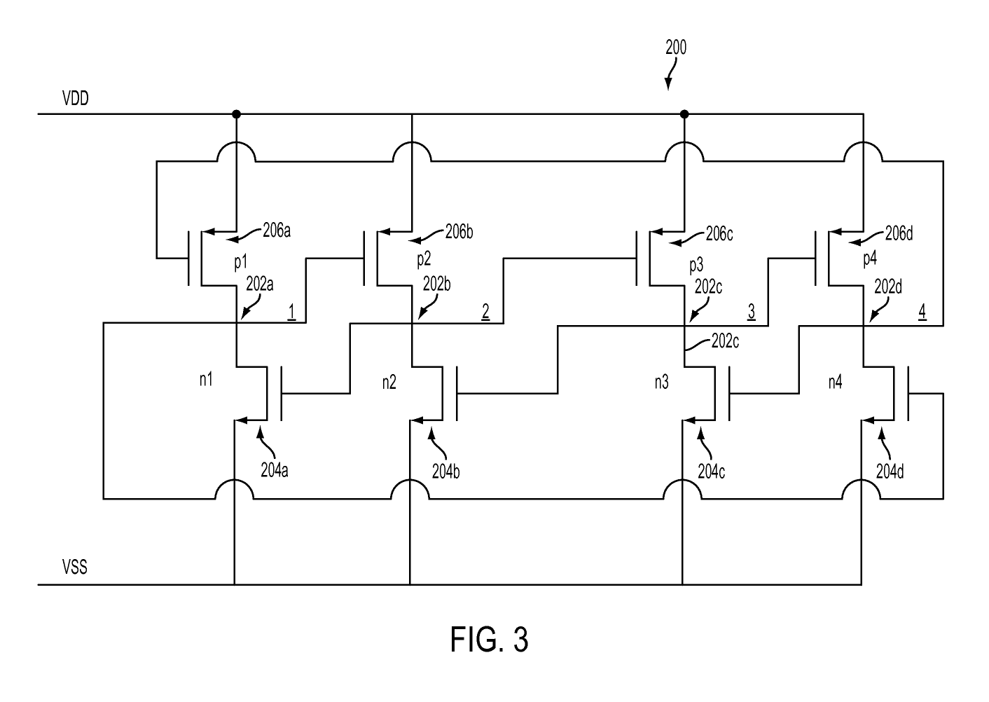

FIG. 3 illustrates one embodiment of a netlist for a Dual Interlocked Cell (DICE) latch cell 200. The DICE latch cell 200 comprises a plurality of nodes 202a-202d. Each of the nodes comprises a pmos/nmos pair. Each n-type MOSFET (metal-oxide-semiconductor field-effect transistor) drain 204a-204d of the plurality of nodes 202a-202d is in an opposing arrangement with a respective p-type MOSFET drain 206a-206d.

In one embodiment, generation of a LEAP circuit comprises two steps: 1) for each state of the circuit, for each contact region in the layout, determine the effect that a single event affecting the contact area has on the circuit state; and 2) use the information in step 1 to layout the circuit in such a way that, for a single event at any position and direction in the layout, the combined effects of the event through all the nodes in the circuit is as small as possible. In some embodiments, the effect of a single event on a node depends on the state of the circuit, for example, on the input to the circuit, and the analysis of a single event on the circuit may be carried through for each possible state, including each possible input state. U.S. Pat. No. 8,495,550, entitled “SOFT ERROR HARD ELECTRONIC CIRCUIT AND LAYOUT,” issued on Jul. 23, 2013 is incorporated herein by reference in its entirety. A redundant LEAP circuit may be referred to as a LEAP^{R} circuit.

In some embodiments, the contact areas in a circuit are placed in a certain relation to each other depending on whether the effects of a single event on the contact areas are opposing or not. The strength of the opposing or non-opposing effect may vary based on, for example, position of the contact areas within the circuit, size of the contact areas, and/or other factors. The effect of a single event on the contact area may be simulated for two (or more nodes). In various embodiments, the effect of a single event on the voltage of a node is determined for each contact area in the circuit. For example, in one embodiment, a single event may cause the voltage of a node to be pulled LOW, pulled HIGH, or pulled towards a voltage value of one or more additional nodes. Once the effects on the nodes connected directly to a contact area are determined, the effect of the single event on the overall circuit state can be determined. The effect of a single event on the overall circuit state may be determined by, for example, simulation of the single event as a stimuli on the circuit. For example, if the effect of a single event is to pull a node LOW, for example, for a source or drain contact area of an n-type MOSFET in bulk semiconductor technology, the stimuli comprises a voltage source and/or a resistive connection to a LOW voltage level. If the effect of the single event is to pull a node towards the voltage value of another node, such as, for example, in MOSFET SOI technology, then the stimuli may comprise a resistive connection between the two nodes.

In one embodiment, when regular circuit simulation (spice type simulation) is applied, the circuit simulation comprises:

| | |
|---|---|
| 1) | for each possible state of the circuit { |

| | |
|---|---|
| a) | Let V₀ₖ be the original voltage in this circuit state on net k in the circuit |
| b) | for each contact area Cᵢ { |

| i) | apply a stimuli corresponding to a single event affecting this contact |
|---|---|
| | area Cᵢ |
| ii) | determine the voltage on each net, k, in the circuit, V₁ₖ |
| iii) | for each contact area Cⱼ (j!=i) { |

| 1) | apply a stimuli corresponding to a single event affecting the |
|---|---|
| | contact area Cⱼ |
| (2) | determine the voltage on each net, k, in the circuit, V₂ₖ |
| (3) | based on the voltage differences on the nets in the circuit in |

step (ii) and step (2) calculate a criterion for the two contact
areas i and j.

}

}

}

In one embodiment, the calculated criterion quantifies how much the two contact areas are opposing or not opposing each other with respect to the effects of the single event on the state of circuit. In one embodiment, the criterion is calculated by the equation:

$${M}_{i , j} = {\sum }_{k}^{all nets} \{ \begin{matrix}sign ( {V}_{1 k} - {V}_{0 k} ) ( {V}_{1 k} - {V}_{2 k} ) , & \vert {V}_{1 k} - {V}_{0 k} \vert > \vert {V}_{2 k} - {V}_{1 k} \vert > Δ V \\ sign ( {V}_{2 k} - {V}_{0 k} ) ( {V}_{1 k} - {V}_{0 k} ) , & \vert {V}_{2 k} - {V}_{1 k} \vert > \vert {V}_{1 k} - {V}_{0 k} \vert > Δ V \\ 0 , & \vert {V}_{1 k} - {V}_{2 k} \vert < Δ V\end{matrix}$$

In another embodiment, the criterion is calculated by the equation:

$${M}_{i , j} = {\sum }_{k}^{all nets} ( {V}_{1} k - {V}_{0 k} ) ( {V}_{1 k} - {V}_{2 k} )$$

In one embodiment, the criterion defines non-opposing effects as negative and opposing effects as positive. A circuit specific criterion may be included. For example, if a sequential cell is analyzed, an upset of the sequential cell could be recorded separately or a multiplier could be applied to such matrix elements in order to force the placement algorithm to consider contact area pairs which generate an upset with the highest priority. In various embodiments, M_{i,j} equals a matrix that defines the effects of a single event at a given contact area for a specific circuit state. The matrix comprises the input information for step 2 of a circuit simulation.

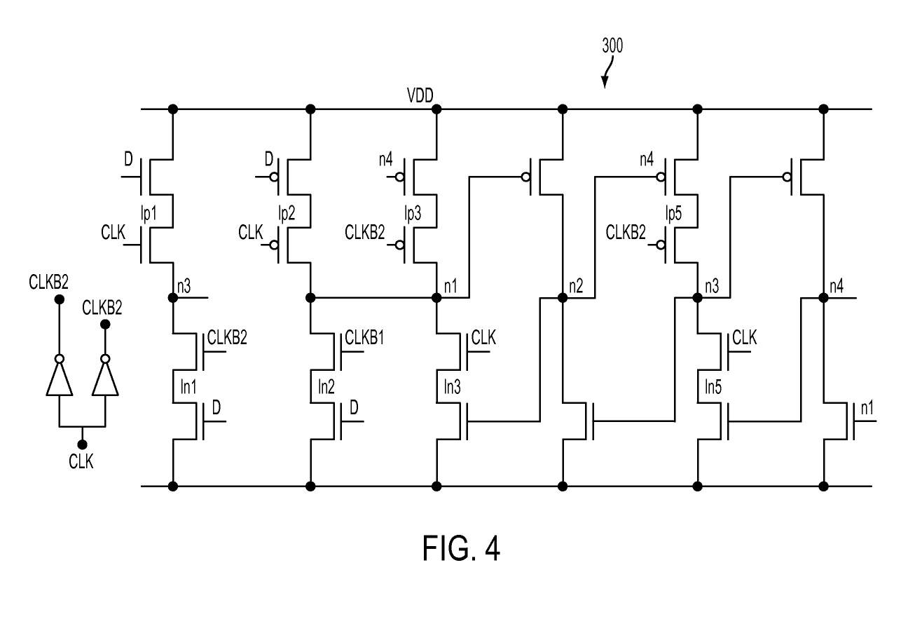

FIG. 4 illustrates one embodiment of a DICE latch 300. The DICE latch 300 comprises a plurality of nodes 304a-304d. In one embodiment, the effect of a single event at each of the nodes 304a-304d is determined, for example, by simulation. The nodes 304a-304d comprise the contact areas of MOSFETs connected to the nets of the circuit. For example, a fourth node 304d comprises two contact areas, one n-type contact area and one p-type contact area. In some embodiments, if one net is connected to two n-type drains or two p-type drains, the two drains are treated as one contact area. In other embodiments, if the two n-type or two p-type contact areas are substantially different, such as, for example, different size or positions relative to other entities in the layout, the two contact areas are treated as different contact areas. The results of a simulation performed on the DICE latch 300 is shown in TABLE 1.

TABLE 1
Matrix generated for the DICE latch 300 of FIG. 4.

| | | dkb1 | dkb1 | dkb2 | dkb2 | n3 | n3 |
|---|---|---|---|---|---|---|---|
| NODE | DRAIN | n | p | n | p | n | p |
| dkb1 | n | 0.00E+00 | 0.00E+00 | 0.00E+00 | 0.00E+00 | 0.00E+00 | 0.00E+00 |
| dkb1 | p | 3.70E+00 | −6.70E−01 | 5.20E−04 | −4.60E−01 | −4.60E−01 | 1.70E−04 |
| dkb2 | n | 0.00E+00 | 0.00E+00 | 0.00E+00 | 0.00E+00 | 0.00E+00 | 0.00E+00 |
| dkb2 | p | 5.30E−04 | −4.60E−01 | 3.70E+00 | −6.70E−01 | 9.10E−01 | 1.90E−01 |
| n3 | n | −1.50E−03 | −1.70E+00 | −1.50E−03 | −8.80E−01 | −6.30E−01 | 2.20E+00 |
| n3 | p | −2.50E−03 | 2.30E−03 | −2.50E−03 | 3.90E−02 | 2.10E+00 | −5.30E−01 |
| in1 | n | 1.00E−11 | −5.10E−07 | −3.00E−11 | 1.30E−03 | −1.80E−06 | 3.00E−11 |
| in1 | p | 0.00E+00 | 2.00E−06 | 0.00E+00 | 1.10E−01 | 0.00E+00 | −4.00E−06 |
| ip1 | n | 0.00E+00 | −1.40E−06 | 0.00E+00 | −2.40E−06 | −9.20E−07 | −3.70E−07 |
| ip1 | p | 0.00E+00 | 1.00E−06 | 0.00E+00 | 1.00E−06 | 0.00E+00 | 0.00E+00 |
| n1 | n | −1.50E−03 | −8.80E−01 | −1.50E−03 | −1.70E+00 | −3.40E+00 | −1.50E−03 |
| n1 | p | −2.50E−03 | 3.90E−02 | −2.50E−03 | 2.30E−03 | −2.50E−03 | −3.50E+00 |
| in2 | n | −4.00E−11 | 1.30E−03 | 0.00E+00 | −5.10E−07 | 4.30E−07 | 1.00E−11 |
| in2 | p | 0.00E+00 | 1.10E−01 | 0.00E+00 | 2.00E−06 | 0.00E+00 | 0.00E+00 |
| ip2 | n | 0.00E+00 | −2.40E−06 | 0.00E+00 | −1.40E−06 | 8.30E−10 | −3.80E−07 |
| ip2 | p | 0.00E+00 | 1.00E−06 | 0.00E+00 | 1.00E−06 | 0.00E+00 | 1.00E−06 |
| in3 | n | −5.80E−06 | −2.00E+00 | −7.30E−06 | −2.20E+00 | −4.50E+00 | −7.10E−06 |
| in3 | p | −2.70E−02 | 4.60E−01 | −2.70E−02 | −2.60E−02 | −2.70E−02 | −3.60E+00 |
| n2 | n | 1.70E−04 | 5.00E−04 | 1.70E−04 | −1.00E−01 | 3.90E−01 | −2.40E+00 |
| n2 | p | −2.50E−03 | −2.40E+00 | −2.50E−03 | −2.10E+00 | −4.30E+00 | −1.10E−03 |
| ip3 | n | −7.90E−02 | −8.00E−04 | −7.90E−02 | −1.90E+00 | −3.80E+00 | −7.90E−02 |
| ip3 | p | −1.90E−05 | 1.20E+00 | −1.40E−05 | −1.50E−05 | −1.40E−05 | −4.40E+00 |
| n4 | n | 1.70E−04 | 1.00E−01 | 1.70E−04 | 5.00E−04 | 4.70E−04 | −4.40E+00 |
| n4 | p | −2.50E−03 | −2.20E+00 | −2.50E−03 | −2.40E+00 | −2.30E+00 | 3.90E−01 |
| in5 | n | −7.30E−06 | −2.20E+00 | −5.80E−06 | −2.00E+00 | −1.70E+00 | 1.10E+00 |
| | | in1 | in1 | ip1 | ip1 | n1 | n1 |
| NODE | DRAIN | n | p | n | p | n | p |
| dkb1 | n | 0.00E+00 | 0.00E+00 | 0.00E+00 | 0.00E+00 | 0.00E+00 | 0.00E+00 |
| dkb1 | p | 5.20E−04 | 5.60E−04 | 5.00E−04 | 5.20E−04 | 9.10E−01 | 1.90E+00 |
| dkb2 | n | 0.00E+00 | 0.00E+00 | 0.00E+00 | 0.00E+00 | 0.00E+00 | 0.00E+00 |
| dkb2 | p | 9.10E−01 | 2.00E+00 | 5.20E−04 | 5.30E−04 | −4.60E−01 | 1.80E−04 |
| n3 | n | −1.50E−03 | −1.50E−03 | −1.50E−03 | −1.50E−03 | −3.40E+00 | −1.50E−03 |
| n3 | p | −2.50E−03 | −2.50E−03 | −2.50E−03 | −2.50E−03 | −2.50E−03 | −3.50E+00 |
| in1 | n | −1.20E−06 | 5.00E−01 | 3.90E−07 | 1.00E−11 | 4.30E−07 | 1.00E−11 |
| in1 | p | 1.60E+00 | −2.90E−01 | 0.00E+00 | 0.00E+00 | 0.00E+00 | 0.00E+00 |
| ip1 | n | 0.00E+00 | −4.30E−07 | −3.10E−01 | 1.60E+00 | 8.30E−10 | −3.80E−07 |
| ip1 | p | 0.00E+00 | 1.00E−06 | 5.00E−01 | 0.00E+00 | 0.00E+00 | 1.00E−06 |
| n1 | n | −1.50E−03 | −1.50E−03 | −1.50E−03 | −1.50E−03 | −6.30E−01 | 2.20E+00 |
| n1 | p | −2.50E−08 | −2.50E−08 | −2.50E−08 | −2.50E−08 | 2.10E+00 | −5.30E−01 |
| in2 | n | 3.40E−08 | 4.60E−09 | 3.90E−07 | 1.00E−11 | 1.80E−06 | 3.00E−11 |
| in2 | p | 0.00E+00 | 1.00E−06 | 0.00E+00 | 0.00E+00 | 0.00E+00 | 4.00E−06 |
| ip2 | n | 0.00E+00 | −4.30E−07 | 5.50E−09 | −3.40E−08 | −9.20E−07 | −3.70E−07 |
| ip2 | p | 0.00E+00 | 1.00E−06 | 0.00E+00 | 0.00E+00 | 0.00E+00 | 0.00E+00 |
| in3 | n | −7.40E−06 | −7.40E−06 | −6.10E−06 | −7.30E−06 | −1.70E+00 | 1.10E+00 |
| in3 | p | −2.70E−02 | −2.70E−02 | −2.70E−02 | −2.70E−02 | 2.50E+00 | −1.90E+00 |
| n2 | n | 1.70E−04 | 1.60E−04 | 1.70E−04 | 1.60E−04 | 4.70E−04 | −4.40E+00 |
| n2 | p | −3.10E−03 | −1.80E−03 | −2.90E−03 | −2.50E−03 | −2.30E+00 | 3.90E−01 |
| ip3 | n | −7.90E−02 | −7.90E−02 | −7.90E−02 | −7.90E−02 | −2.20E+00 | 2.40E+00 |
| ip3 | p | −1.40E−05 | −1.20E−05 | −1.40E−05 | −1.50E−05 | 1.30E+00 | −1.40E+00 |
| n4 | n | 1.70E−04 | −1.40E−04 | 2.40E−04 | 9.20E−05 | 3.90E−01 | −2.40E+00 |
| n4 | p | −2.50E−03 | −2.50E−03 | −2.50E−03 | −2.50E−03 | −4.40E+00 | −1.10E−03 |
| in5 | n | −1.50E−05 | −2.40E−06 | −1.10E−05 | −7.50E−06 | −4.50E+00 | −7.10E−06 |

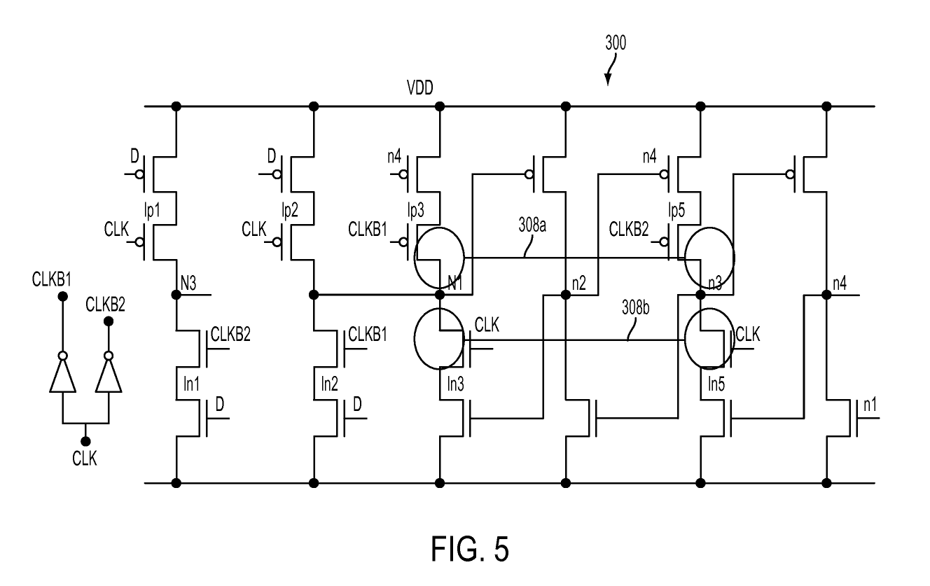

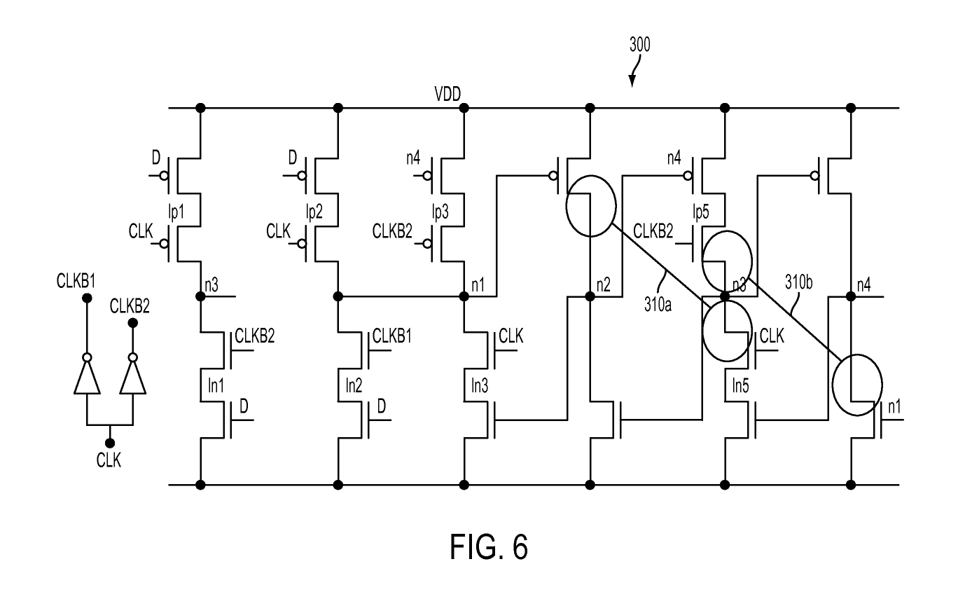

The average over all four states of the latch circuit are shown in TABLE 1. FIG. 5 illustrates a single event that effects the contacts areas of a p-type MOSFET and an n-type MOSFET connected to the same circuit net 302c. The n-type and the p-type drains have opposing effects (positive matrix entry) for the single event. Two n-type contact areas comprise non-opposing (negative matrix entry) responses for the single event. FIG. 6 illustrates non-opposing nodes in the DICE latch 300. The non-opposing nodes comprise strong non-opposing single event responses. For example, as shown in TABLE 1, the coupling between the contact areas of the first node 304a and the third node 304c have a non-zero, non-opposing effect.

In one embodiment, the placement of the contact areas in the layout of the integrated circuit is guided by which nodes are opposing and non-opposing. Additional circuit considerations, such as, for example, routing considerations, effects on switching speed, power, layout area, or other circuit considerations affect the placement of opposing and non-opposing nodes. The placement of a contact area in the circuit may comprise, for example, an iterative process which considers one or more performance considerations. In some embodiments, the iterative placement process comprises generating a first layout and analyzing the generated layout with respect to single event soft error performance. A 3D structure simulation may be used. U.S. Patent App. Pub. No. 2009/0044158, published on Feb. 12, 2009, entitled “METHOD, AND EXTENSIONS, TO COUPLE SUBSTRATE EFFECTS AND COMPACT MODEL CIRCUIT SIMULATION FOR EFFICIENT SIMULATION OF SEMICONDUCTOR DEVICES AND CIRCUIT,” is incorporated herein by reference in its entirety. In other embodiments, one or more additional and/or different simulation methods may be applied. Subsequent layouts are generated with different criteria for the contact area placement, and analyzed. The iteration proceeds until no further improvements in the soft-error performance and/or improvements in other performance criteria are achievable.

The soft-error criteria in the contact area placement are used to determine the relative order among the contact areas along certain directions in the layout. The directions within the layout are referred to as R-directions. In one embodiment, the placement of the contact areas comprises a deterministic process utilizing rules guiding each step. In another embodiment, the placement of the contact areas comprises a statistical process in which relative contact area placements are generated by a random process and rejected or accepted depending whether the generated placements fulfill the implemented rules, such as, for example, placement of n-type and p-type contact areas in opposing and non-opposing relationships. For larger circuits, a deterministic process may be preferred, as the number of possible node-orderings can become unmanageable, and a random placement would have to explore both one dimensional placement (with all contact areas along a single R-direction), and two dimensional placements. For example, if no constraints are used, the number of possible relative placements in a one dimensional placement for just 12 contact areas would be 12!=4.8e8.

In some embodiments, a deterministic placement process groups the nodes according to how the nodes are coupled. Contact areas that belong to the same MOSFET, and therefore must be physically adjacent, are grouped as device groups. The device groups are placed together. As used herein, the term “contact area” may refer to a single contact area and/or a device group. Under almost all circumstances, two contact areas of the same MOSFET will have the same single event effect on the circuit and will be opposing or non-opposing with respect to the other contact areas and therefore can be treated as a single contact area.

In some embodiments, a deterministic process comprises selecting a first contact area pair, C₀ and C₁, with non-zero, non-opposing single event effects. For example, in one embodiment, a first contact pair comprises a contact pair having the strongest non-opposing effect. The line in the layout between the two contact areas of the first contact pair defines the first R-direction, or R-line, R₀. The first contact area, C₀, is placed in the layout.

A set of C₀-positive contact areas comprising one or more contact areas having an opposing effect with respect to C₀ are identified. If a matrix is generated for the circuit, for example, as illustrated in TABLE 1, the set of C₀-positive contact areas comprise a positive coefficient in the row of C₀. A C₀-positive contact area C₂ is selected. In one embodiment, C₂ comprises the contact area with the largest opposing effect with respect to C₀. The positive contact C₂ is placed next to C₀ in the first direction R₀.

A set C₀-negative contact areas comprising one or more contact areas having a non-zero, non-opposing effect with respect to the contact area C₀ are identified. The contact area C₁ is included in the set of C₀-negative contact areas. A contact area C₃ is selected from the set of C₀-negative contact areas. In one embodiment, C₃ comprises the contact area, excluding C₁, with the largest non-opposing effect with respect to C₀. A line in the layout between C₀ and C₃ comprises a second R-direction, R₁.

In one embodiment, a second contact area, C₄, is selected from the set of C₀-positive contact areas and is placed next to C₀ in the R₁ direction. The direction R₁ comprises any direction, different from R₀, that is permitted by the geometrical restrictions of fitting the contact areas into the available space. In some embodiments, R₁ is orthogonal or anti-parallel to R₀. In some embodiments, if at any point in the placement two contact areas along different directions have a non-zero, non-opposing effect, then the two directions are made parallel or anti-parallel. The placement of contact areas comprising non-zero, non-opposing effects may depend on the strength of the non-opposing effect. For example, in one embodiment, if there is a non-zero, non-opposing effect between contact area C₁ and C₃ or C₄, or between C₂ and C₃ or C₄, then R₁ may be anti-parallel to R₀, as R₁ cannot be parallel as the spot next to C₀ in the parallel direction R₀ is already taken by C₂. In some embodiments comprising small and medium sized circuits, all nodes will be placed along the same R-direction in the circuit.

In one embodiment, contact area C₄ is placed adjacent to contact area C₀ in the R₁ direction. The remainder of the contact areas in the set of C₀-positive are placed until all contact areas have been used or until all positions adjacent to C₀ are occupied by a contact area. The same analysis as for C₀ is performed for each of the contact areas placed adjacent to C₀. As the analysis progresses through nodes adjacent to C₀, the R-directions and/or the prior placement of nodes must be maintained. For example, when the analysis proceeds to C₂, if C₂ comprises a non-zero, non-opposing effect with respect to C₄, then a selected opposing node must be placed along the R-direction already determined for C₄, R₁. In some embodiments, if only a direction has been determined for a contact area, but the contact area has not been placed, a change in the direction is permitted so long as there is an opposing contact area between the contact area and every other contact area which has a non-zero, non-opposing effect with respect to the contact area.

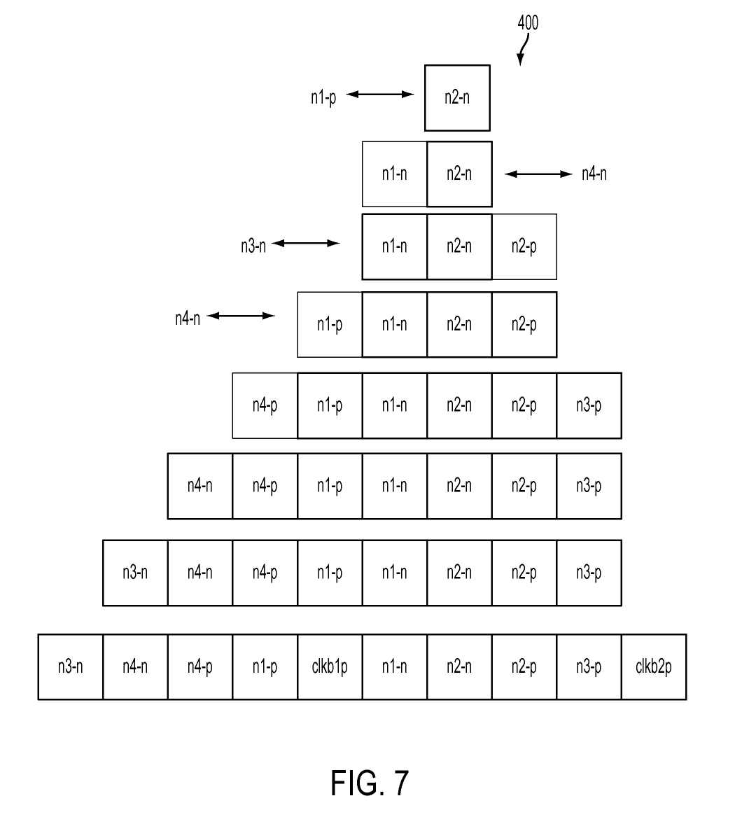

Placement of the contact areas proceeds until all contact areas have been placed. In some embodiments, the deterministic placement process is configured to handle contact areas that cannot be placed according to the deterministic process described above, such as, for example when a first node lacks any opposing effects with a second node. In some embodiments, all possible positions for the contact areas are considered, including inserting the first node in-between two already placed nodes. In another embodiment, the position of each contact area is selected such that the contact area's position optimizes the opposing effects of adjacent contact areas for all placed contact areas in the circuit. In this embodiment, the sum of the matrix elements for all placed adjacent pairs is maximized and may comprise inserting a new contact area between two existing pairs. As above, coupling of pairs that belong to different R-directions is considered and the R-directions may be forced to parallel or anti-parallel positions if the inter-R-direction effect is too large for the criterion used. In some embodiments, the contribution of each contact area adjacent to a contact area which is adjacent to the currently analyzed contact area is considered. These contact areas may be referred to as neighbor contact areas. The effect contributed by neighbor contact areas will be less strong than the effect from adjacent contact areas. FIG. 7 illustrates one embodiment of a deterministic placement process 400 for the DICE latch circuit illustrated in FIG. 3.

In various embodiments, multiple placement positions are available for each contact area. The multiple placement positions may result in equivalent circuits, for example, circuits obtained through a cyclic permutation of the contact areas. In some embodiments, equivalent circuits are ignored. Constraints related to geometry and routing can be applied in the selection of contact area placement and may further reduce the number of resulting non-equivalent layouts. If the number of non-equivalent layouts is large, one or more contact areas may be identified and a placement selected based on the strength of the opposing and/or non-opposing effects at the corresponding points of selection.

In some embodiments, one or more contact areas are grouped together. As noted above, contact areas of the same MOSFET comprise a device group. Additional groupings may be made based on, for example, power, space, processing, and/or other requirements. In some embodiments, all contact areas in a group comprise the same single event effect with respect to all other contact areas in the circuit. In some embodiments, a grouping preference is considered in the selection of contact areas in the placement process. For example, if there is a choice between contact areas to place adjacent to a specific contact area, contact areas comprising a group are preferentially selected. In some embodiments, the strength of the opposing or non-opposing effect used in the selection process comprises the value from the contact area in the group which is closest to the adjacent contact area or group. In other embodiments, the strength of the opposing or non-opposing effect comprises the average value for all the contact areas in the group.

The two-step analysis and layout generation is performed for individual blocks or cells in the total circuit. Layouts are created for each cell. By generating layouts for individual cells, the complexity of the two-step analysis and layout generation is reduced. The generated cells comprise circuit elements, such as, for example, sequential or combinational logic gates, such as flip-flop, NAND, NOR, XOR gates, half-adders, and/or other sequential and/or combinational logic elements. The individual circuit cells are combined and connected to form a complete integrated circuit. In some embodiments, the layouts of the individual cells are arranged to reduce the effects of a single event in any one contact area on the circuit. The individual cells are placed according to the arrangements discussed herein, such as, for example, placement of opposing and non-opposing cells to limit the effects of a single event.

In some embodiments, placement of individual cells comprises identifying non-opposing contact areas in two different cells. If two non-opposing nodes from different individual cells cannot fulfill placement requirements, the circuit may be rearranged such that the circuit nets of the two contact areas no longer couple in the circuit and therefore cannot have a non-zero, non-opposing effects with respect to each other. In particular, for cells that have all contact areas along one R-direction (R₀), then in the direction perpendicular to the R-direction, R₁, there will be no contact areas with opposing effects. If two cells of this type are placed in a direction perpendicular to the R-direction of both cells, then, unless the circuit is such that it decouples the two cells, one contact area in the first cell may have a non-zero, non-opposing effect with respect to a node in the second cell, and there will be no contact areas in-between with an opposing effect. If, however, the line of the R-direction of both cells coincide, such as, for example, the second cells is placed next to the first cell in the R₀ direction, then it is possible to ensure that opposing contact areas are between non-opposing contact areas, even if the two contact areas are from different cells.

The inter-cell placement rules analyze how two individual cells are coupled. If the coupling in the circuit is such that there are non-opposing effects between contact areas of two individual cells, then the cells may be placed along the same R-line and/or a filter may be inserted between the cells. In one embodiment, placement of each LEAP cell within a circuit may comprise:
1) Classification of each LEAP cell:
   a) Identify, for each LEAP cell, the direction(s) for each cell output, along which the contact areas are placed (the R-direction).
2) Given a first LEAP cell, analyze the coupling between the nodes in one or more LEAP cells to which the first cell is connected in the circuit. If there is a non-zero non-opposing coupling (of a certain magnitude) between a contact area in the first LEAP cell and a contact area in a second LEAP cell, the second LEAP cell is placed such that the second LEAP cell's R-direction coincides with the R-direction of the first LEAP cell and if the cells are abutted, with an orientation such that the abutment is between two contact areas, one from each cell, that either belong to the same circuit node, or have opposing effects.
3) If rule two cannot be fulfilled, and the distance between the cells is below a certain critical distance (L_{crit}), introduce a LEAP filter cell. The filter and the second leap cell are connected such that the layout fulfills rule two.
   In one embodiment, the LEAP filter cell is configured to remove the non-opposing single event coupling between the first LEAP cell and the second LEAP cell. For a dual redundant inverse (DIR) logic circuit, the filter will filter any single event pulses where the both the primary data signal and the redundant inverse data signal have the same voltage.

In some embodiments comprising multiple outputs, a LEAP cell may comprise several R-directions. Each R-direction is paired with R-directions in adjacent cells depending on how the cells are connected in the circuit. The placement and filter insertion rules are applied for each paired R-direction of the adjacent cells. In some embodiments, the primary and redundant sides of the cell in the R-direction are determined by the contact areas next to the edge of the cell. For example, if the contact areas next to a first edge of the cell are connected to a circuit net that carries the primary signal, the first edige is primary and if the contact areas next to a second edge of the cell are connected to the redundant signal, the second edge is redundant. In some embodiments, side-classification is coupled to the internal intra-cell LEAP methodology. This rule refinement/optimization will take into account not only the net connected to the contact areas next to edge of the cell, but also whether they are p-drains or n-drains, for example, to determine the explicit effect of a single event on the node. The optimization process may take into account several contact areas in each of the abutted cells.

In some embodiments, if the distance between two cells is large, a non-zero, non-opposing coupling between two cells is ignored. The distance at which a non-zero, non-opposing coupling is ignored, L_{crit}, is determined by application specifications and/or by information about the probability of a single event hitting both of the cells, such as, for example, from simulation and/or experimental data. A finite L_{crit} is introduced to reduce the number of filter cells introduced to the layout. In one embodiment, an infinite L_{crit} may be defined, resulting in a filter being inserted between all non-zero, non-opposing couplings regardless of distance.

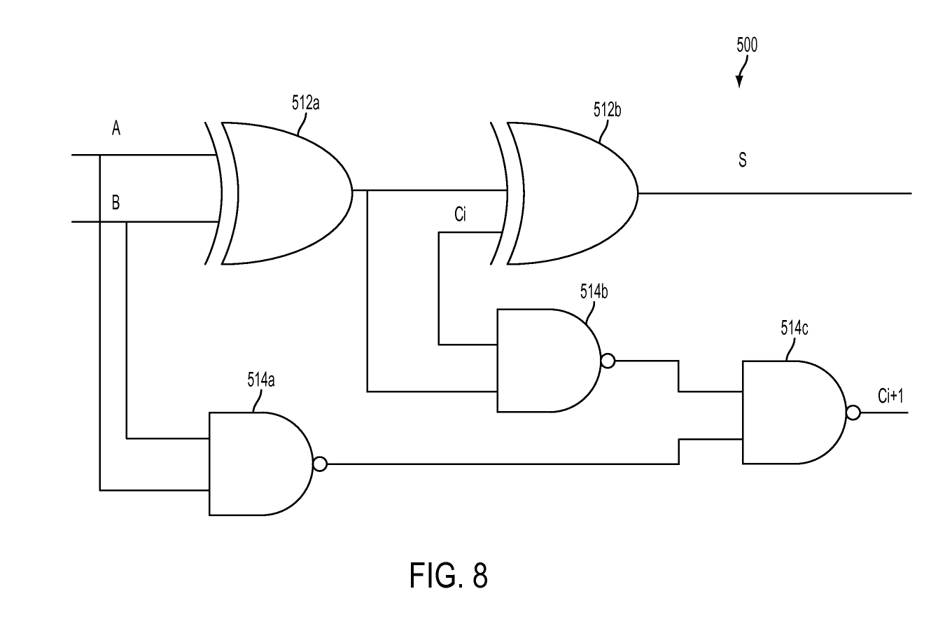

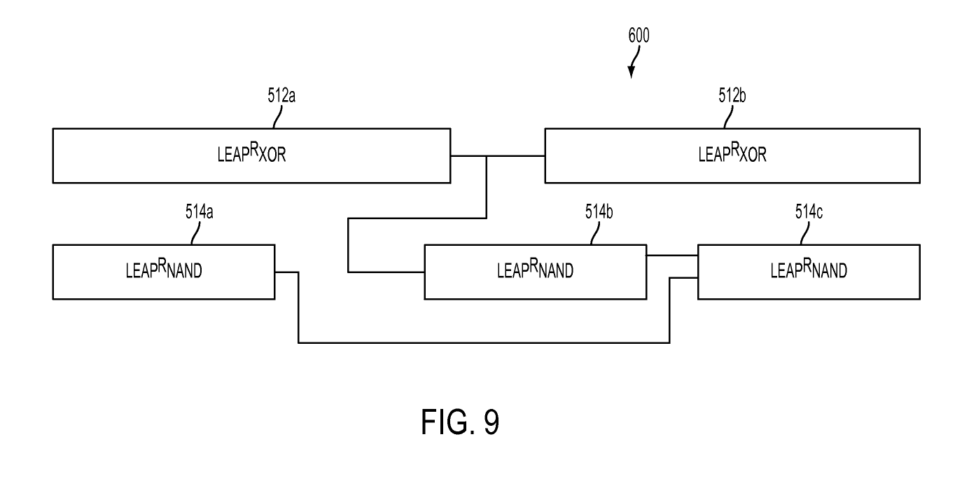

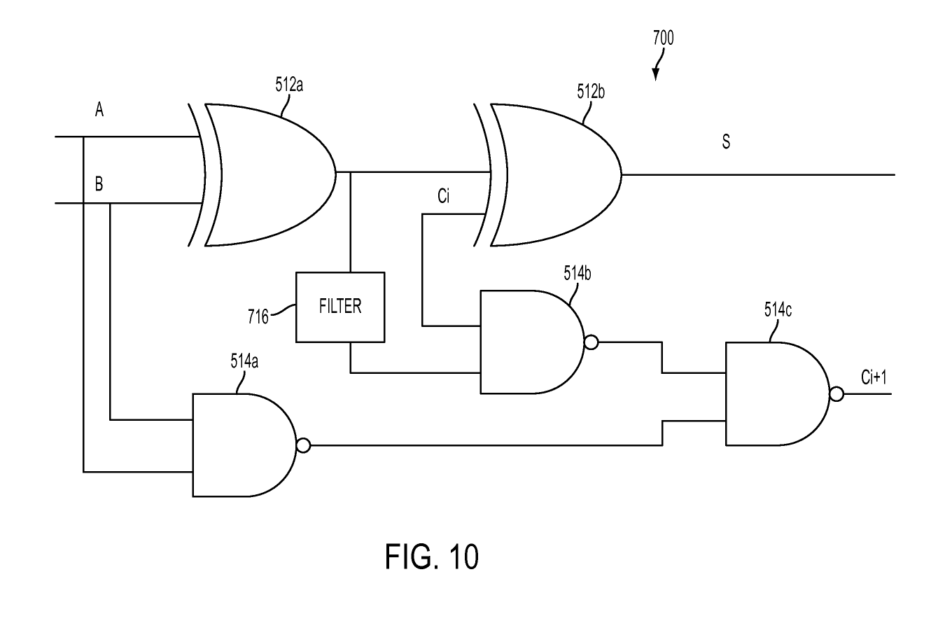

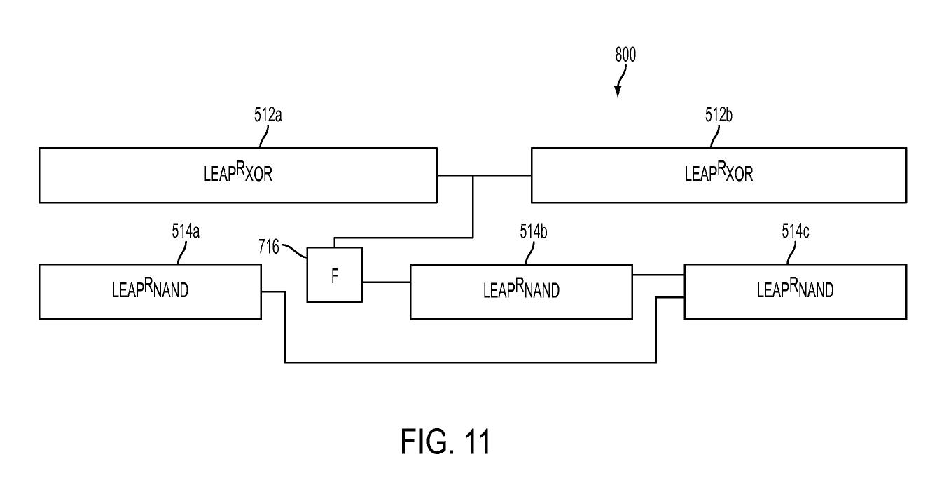

FIGS. 8-11 illustrate one embodiment of filter insertion in a 1-bit adder circuit comprising dual inverse redundant (DIR) logic. FIG. 8 illustrates an original 1-bit adder netlist 500. The 1-bit adder comprises a plurality of DIR NAND 514a-514c and DIR XOR 512a-512b logic gates. The principle layout 600 of the 1-bit adder is illustrated in FIG. 9. According to the rules discussed above, a filter must be inserted when the layout of FIG. 9 is used. A 1-bit adder 700 with a filter 716 inserted is shown in FIG. 10. The final principle layout 800 of the 1-bit adder circuit is shown in FIG. 11.

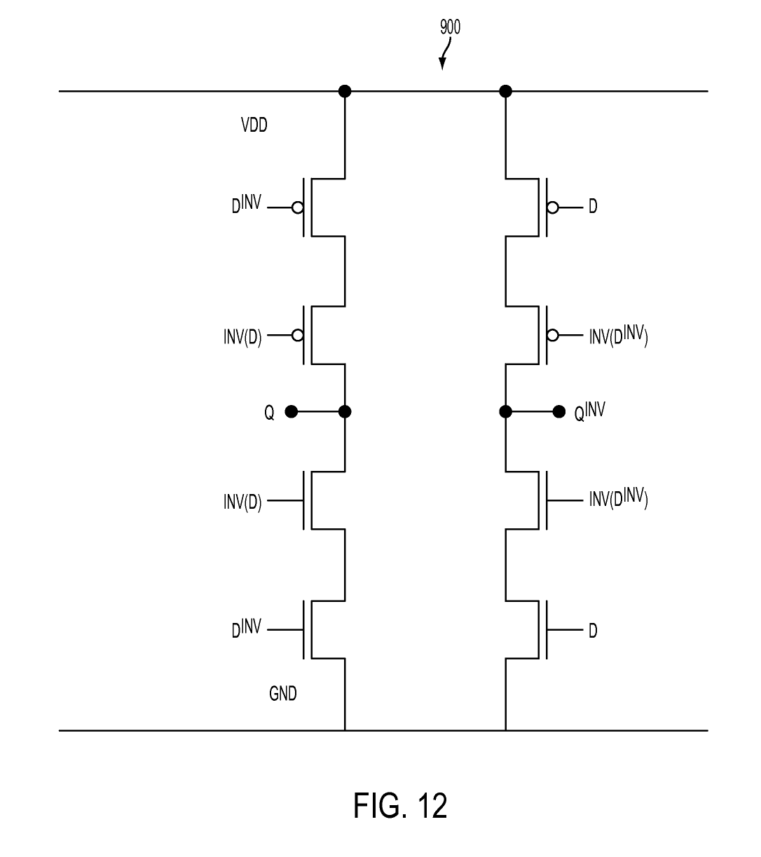

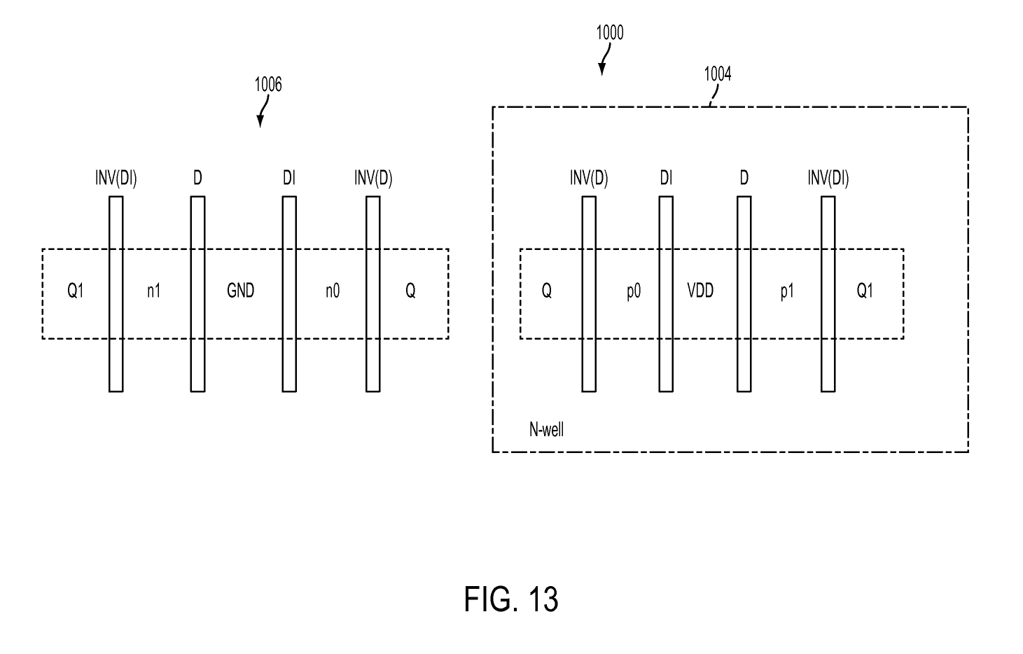

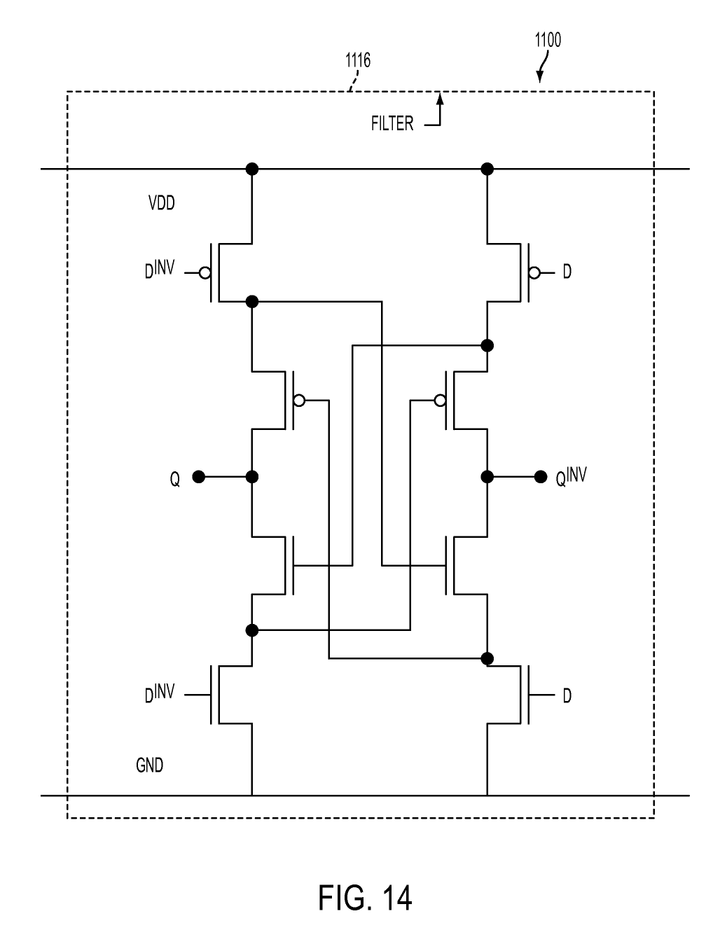

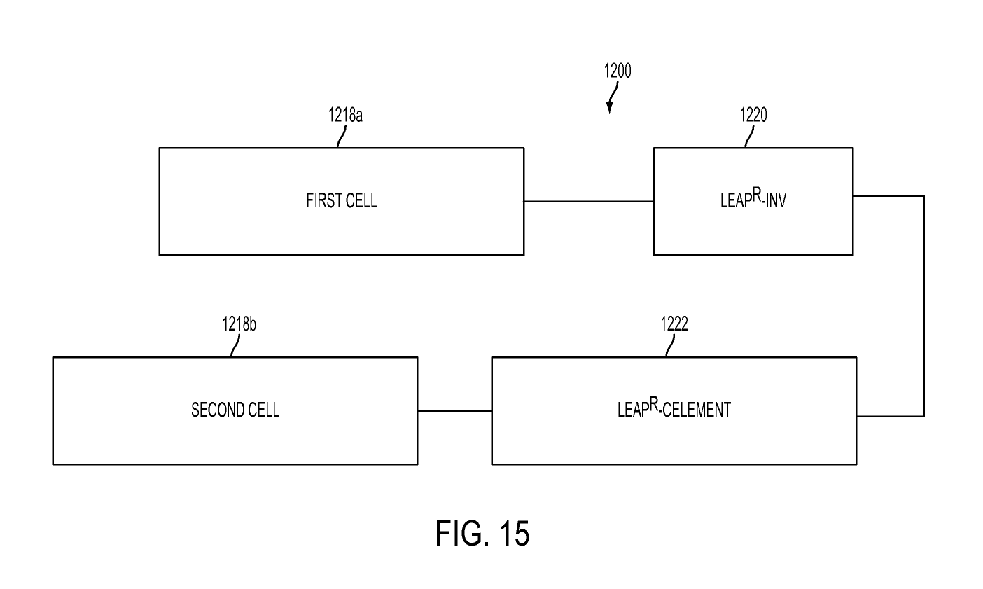

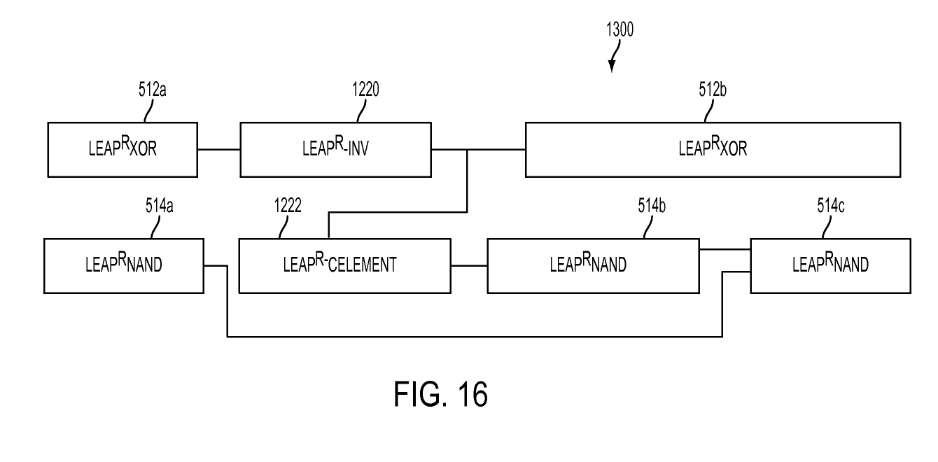

FIG. 12 illustrates one embodiment of a filter cell 900 comprising a combination of two c-elements. The combination of c-elements filter the signal when the two input signals are the same, but passes the signal when one input is the inverse of the other input. The filter circuit may be referred to as a LEAP^{R} c-element. A LEAP^{R} c-element layout 1000 is illustrated in FIG. 13. In one embodiment, the input signals comprising the inverse of the data signal, D, and the inverse of the inverse data-signal, inv(D^{inv}), must be generated, that is, the signal D cannot be used in place of inv(D^{inv}). In some embodiments, such as the embodiment illustrated in FIG. 14, the inv(D^{inv}) signal is an internal signal of the LEAP^{R} c-element 1100. In other embodiments, an inverter, which is itself a LEAP layout cell, generates the inverse and inv(D^{inv}) signals. A LEAP^{R}-INV (LEAP^{R} inverter) cell comprises a logic cell preceding the LEAP^{R} c-element and placement of the LEAP^{R} c-element adheres to the LEAP inter-cell placement rules. FIG. 15 illustrates one embodiment of a layout 1200 comprising a LEAPR-INV 1220 and a LEAP^{R} c-element 1222 relative to a preceding cell 1218a and a following cell 1218b. FIG. 16 illustrates a placement arrangement 1300 for the 1-bit adder circuit of FIG. 12 comprising a filter input generated by a LEAP^{R}-INV cell 1220.

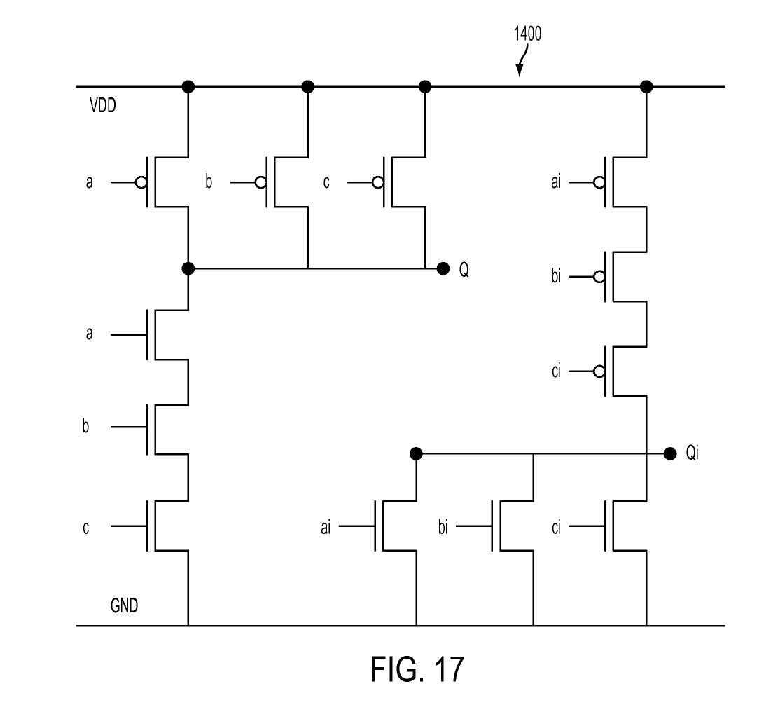

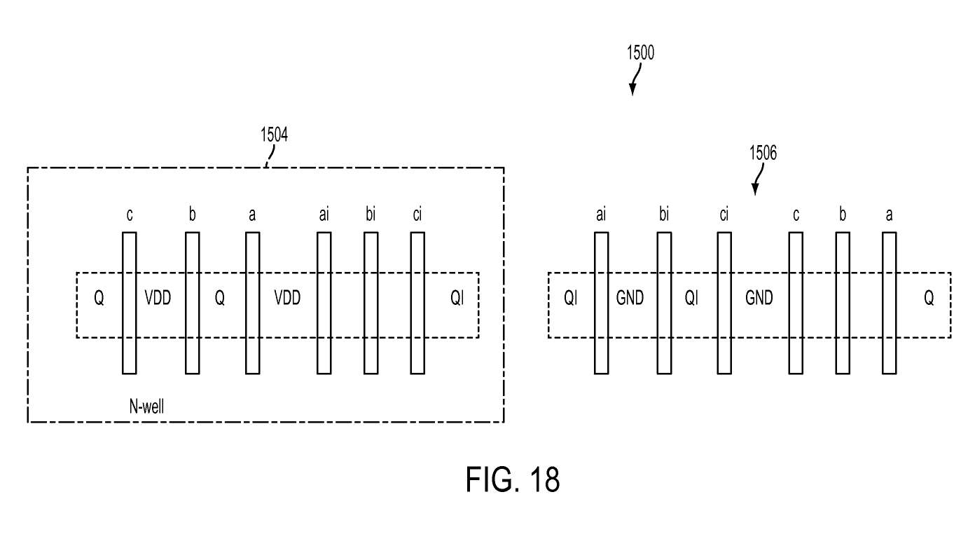

FIG. 17 illustrates one embodiment of a LEAP^{R} NAND3/NOR3 logic circuit 1400. The inputs a, b, and c are the primary data inputs and ai, bi, and ci are the inverse of data inputs a, b, and c. The gates of a, b, and c may be interchanged and the gates of ai, bi, and ci may be interchanged. FIG. 18 illustrates one embodiment of a principle layout 1500 for the reverse redundant logic NAND3/NOR3 logic cell 1400. The truth table of the NAND3/NOR3 logic circuit 1400 is provided in TABLE 2.

TABLE 2
LEAP^{R}NAND3

| | | | | | | output | DIR |
|---|---|---|---|---|---|---|---|
| input | | | | | | NAND3 | NOR3 |
| a | b | c | ai | bi | ci | Q=!(a&b&c) | Qi=!(ai\|bi\|ci) |
| 0 | 0 | 0 | 1 | 1 | 1 | 1 | 0 |
| 0 | 0 | 1 | 1 | 1 | 0 | 1 | 0 |
| 0 | 1 | 0 | 1 | 0 | 1 | 1 | 0 |
| 0 | 1 | 1 | 1 | 0 | 0 | 1 | 0 |
| 1 | 0 | 0 | 0 | 1 | 1 | 1 | 0 |
| 1 | 0 | 1 | 0 | 1 | 0 | 1 | 0 |
| 1 | 1 | 0 | 0 | 0 | 1 | 1 | 0 |
| 1 | 1 | 1 | 0 | 0 | 0 | 0 | 1 |

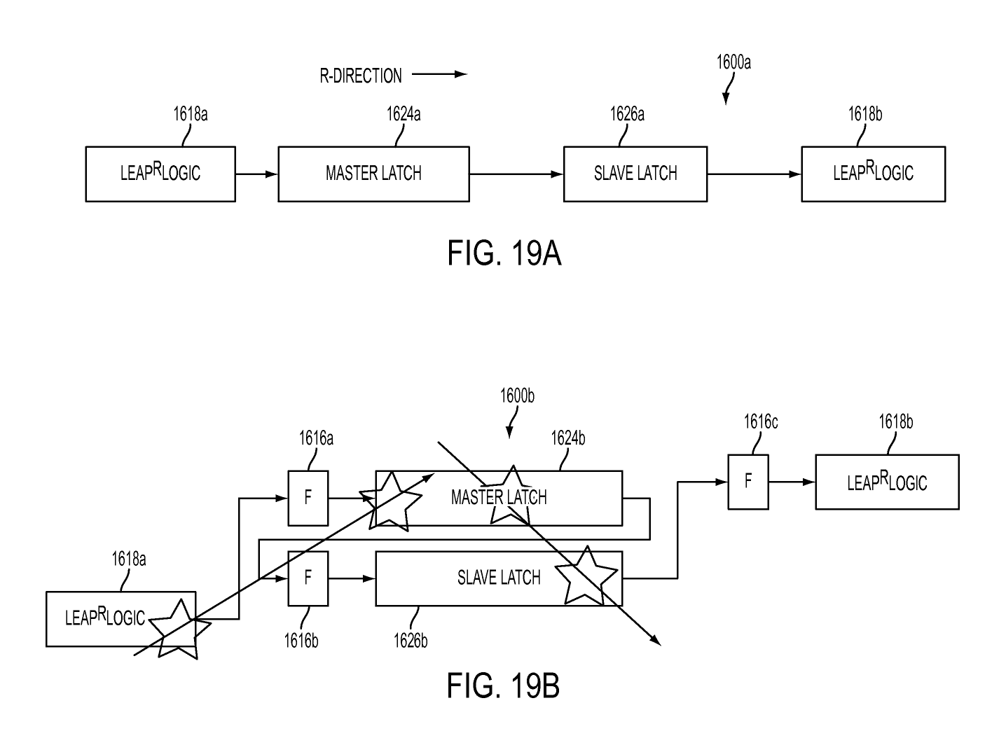

FIGS. 19A and 19B illustrate various embodiments of a LEAP^{R} flip-flop circuits 1600a, 1600b. The LEAP^{R} systems and methods described above are configured to prevent single error events from affecting a logic cell. In some embodiments, a flip-flop cell may be affected by a combination of two transient pulses generated in two different cells, for example, in a master latch and a slave latch, in a preceding logic gate and the master latch, or in a following logic gate and the slave latch. If two such pulses occur on two redundant nets at the time the data is clocked into the slave latch and/or master latch, an erroneous data logic value can be clocked.

If the master latch and slave latch are adjacent, two pulses which generate an error pulse on two different nets in the master latch and slave latch, respectively, can combine in the slave latch. If the error pulses are generated at the same time that a clock signal occurs which clocks in data into the slave latch, then an erroneous data value can be clocked into the slave latch. A similar situation occurs if two pulses in the master latch and in a preceding logic element combine in the master latch at the time of a clock signal, or if two pulses, one in the slave latch and one in a following logic element combine in the master latch of the next flip-flop at the time of a clock signal.

FIGS. 19A and 19B illustrate various embodiments of the LEAP^{R} flip-flop cells 1600a, 1600b configured to prevent two error pulses from combining to create an error in the master latch and/or the slave latch. In the embodiment shown in FIG. 19A, the master latch 1624 and slave latch 1626 are placed along the same R-direction. In the embodiment shown in FIG. 19B, filters 1616a-1616c are placed between the preceding logic cell 1618a, the master latch 1624, the slave latch 1626, and the following logic cell 1618b. The filters 1616a-1616c filter the signal when an error occurs on one of the data paths and prevents two error pulses from two different logic cells from combining to create an error on both logic data paths. In some embodiments, a filter cell 1616a-1616c comprises a LEAP^{R} c-element filter. In other embodiments, a filter cell 1616a-1616c comprises an integrated special extension to the part of the DICE circuit that clocks in the signal to the master latch and/or the slave latch.

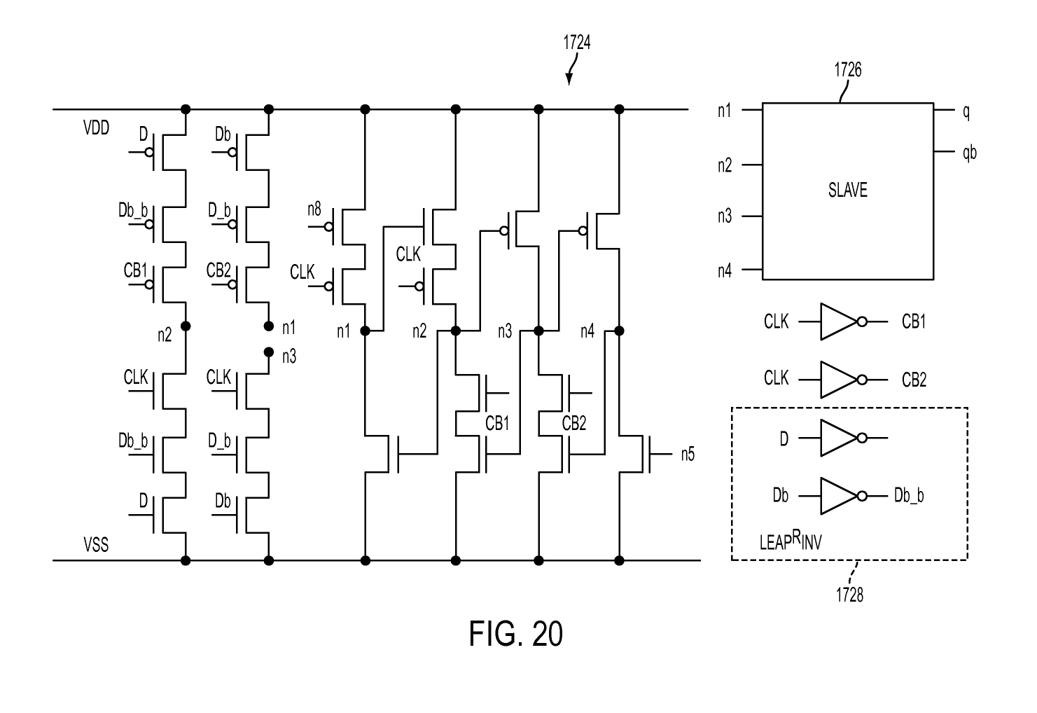

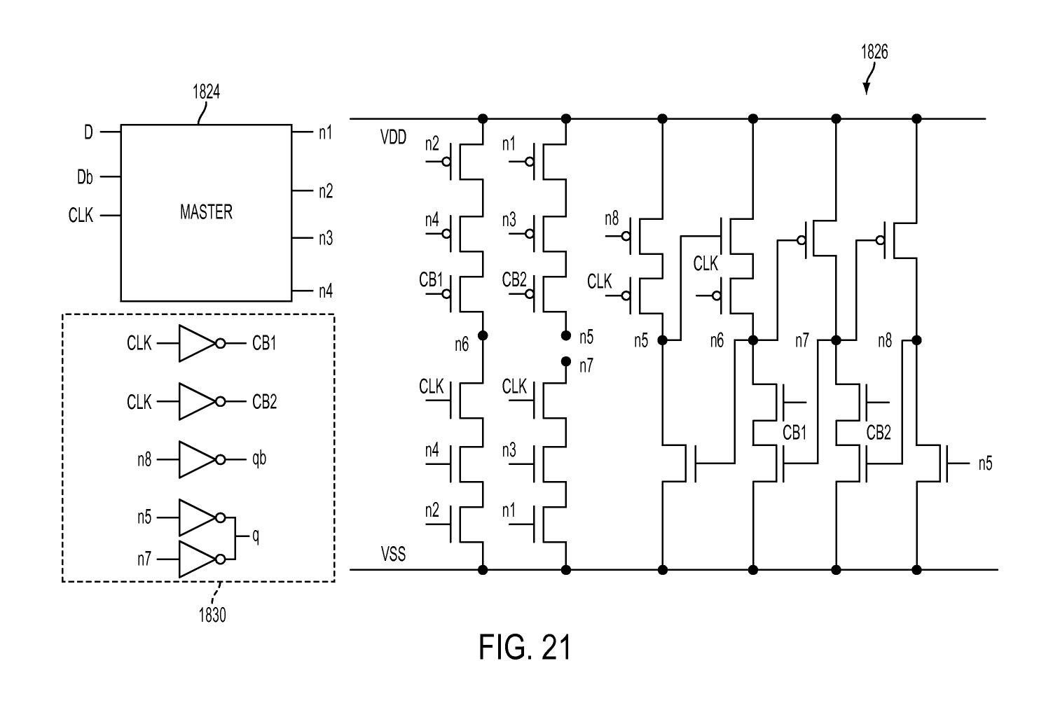

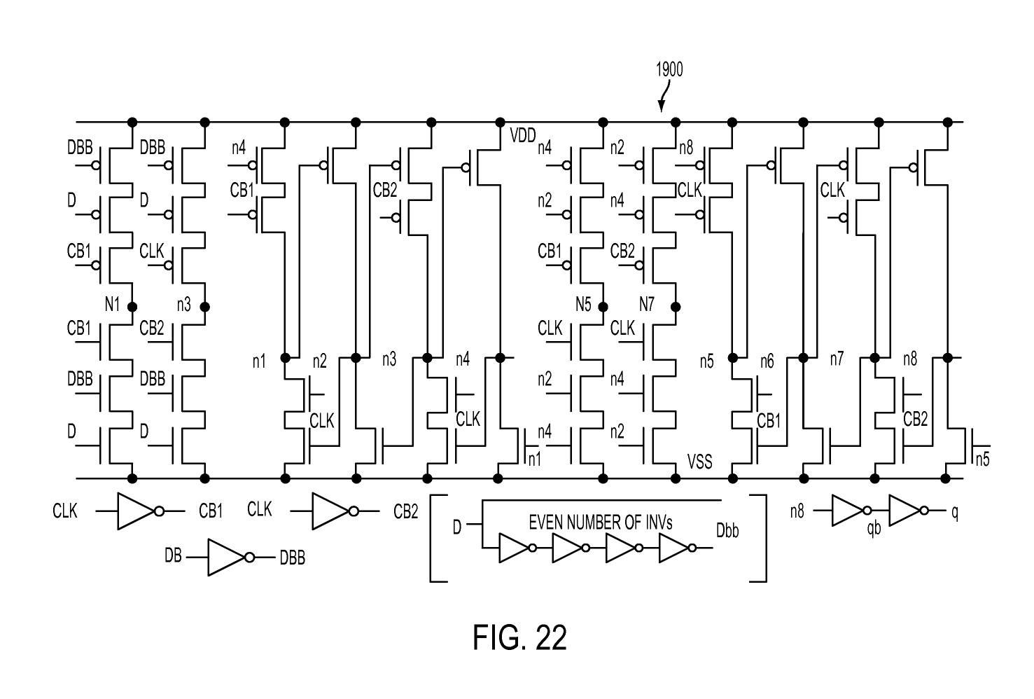

In one embodiment, each MOSFET device comprising a data signal gate input is replaced with two MOSFETs in series, where by a first MOSFET takes a data signal gate input from a first path of a dual redundant data path, and a second MOSFET takes a data signal gate input from a second path of the dual redundant data path, which under normal operation has the same value as the first path. FIG. 20 illustrates one embodiment of a SET filter insertion for a master filter-clocking latch 1724. The slave latch 1726 and the LEAP^{R}-INV input 1728 are illustrated in block format. FIG. 21 illustrates one embodiment of SET filter insertion for a slave filter-clocking latch 1826. The master latch 1824 and the inputs 1830 are illustrated in block format. FIG. 22 illustrates one embodiment of a DICE circuit 1900 comprising tri-state clocking. A parallel MOSFET is integrated into the DICE circuit to provide filtering and prevent two pulse errors.

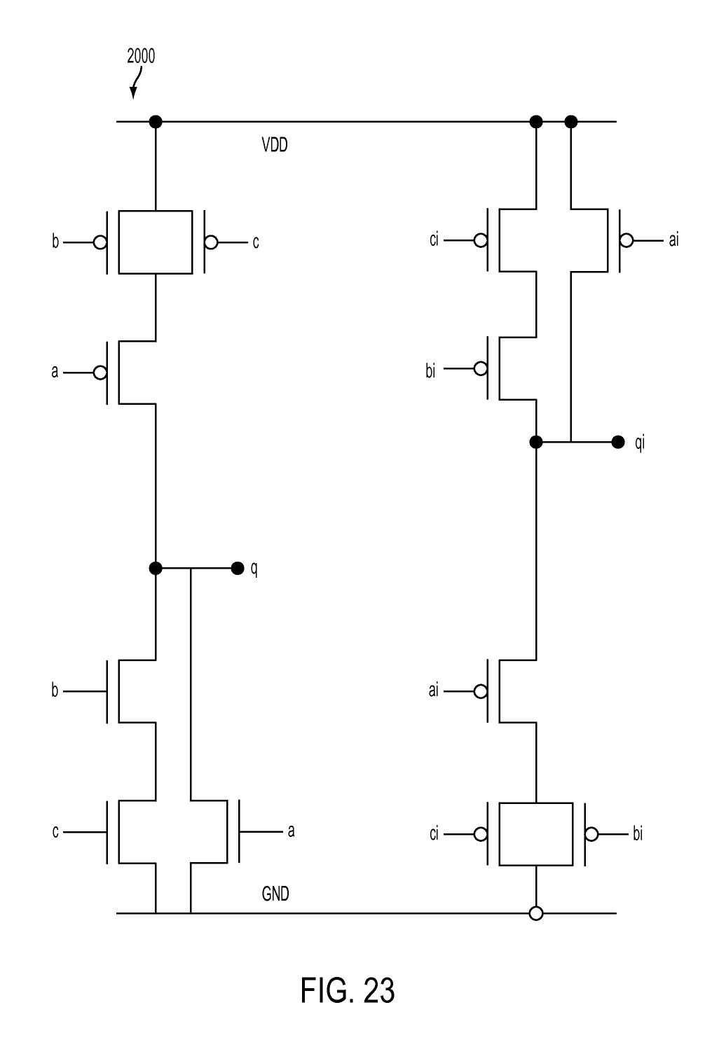

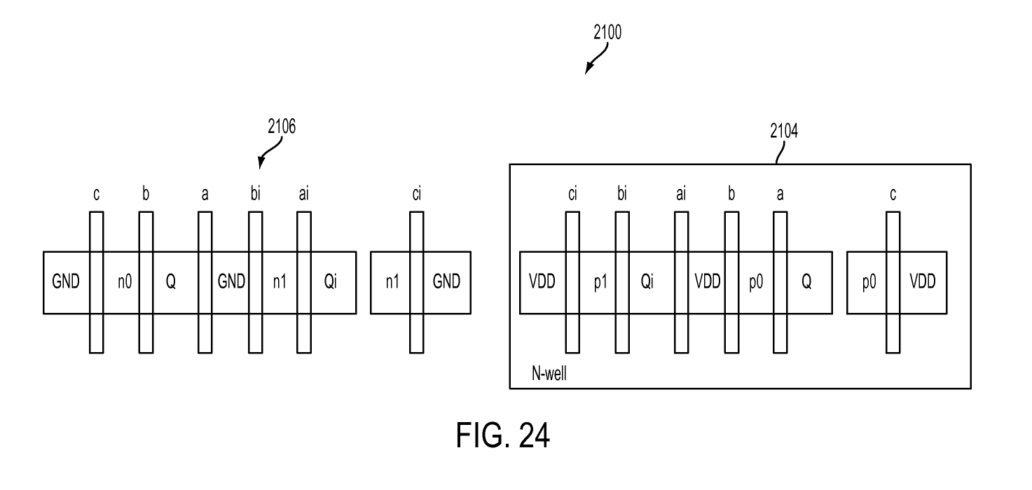

FIG. 23 illustrates an AOI21 gate integrated with a complementary, or dual-inverse-redundant (DIR) gate, according to the LEAP methodology. The circuit 2000 illustrated in FIG. 23 may be referred to as a LEAP^{R}AOI21 gate. A truth table for the DIR gate is illustrated in TABLE 3. FIG. 24 illustrates one embodiment of a preferred layout 2100 for the LEAP^{R}AOI21 gate.

TABLE 3
LEAP^{R}AOI21

| | | | | | | output | |
|---|---|---|---|---|---|---|---|
| input | | | | | | AOI21 | DIR |
| a | b | c | ai | bi | ci | Q=!(a\|(b&c)) | Qi=!(ai&(bi\|ci)) |
| 0 | 0 | 0 | 1 | 1 | 1 | 1 | 0 |
| 0 | 0 | 1 | 1 | 1 | 0 | 1 | 0 |
| 0 | 1 | 0 | 1 | 0 | 1 | 1 | 0 |
| 0 | 1 | 1 | 1 | 0 | 0 | 0 | 1 |
| 1 | 0 | 0 | 0 | 1 | 1 | 0 | 1 |
| 1 | 0 | 1 | 0 | 1 | 0 | 0 | 1 |
| 1 | 1 | 0 | 0 | 0 | 1 | 0 | 1 |
| 1 | 1 | 1 | 0 | 0 | 0 | 0 | 1 |

In some embodiments, abutting contact regions are constrained such that two abutting contact regions are from the same net, for example, either primary-primary or redundant-redundant. Several different primary-primary or redundant-redundant abutments may be possible for each circuit element, such as, for example, in CMOS logic in which the output nodes of logic gates are connected both to a drain of a p-type MOSFET (p-type contact area), and to a drain of an n-type MOSFET (n-type contact area). The primary-primary or redundant-redundant abutment ensures that a single event that affects only the two abutment contact regions cannot cause an error on both outputs. However, if the next contact region inside either cell, which belongs to a different net is also affected, an error may occur.

In some embodiments, the effects of an error on both an abutted contact region of a first net and the next contact region of a second net is limited by abutting contact regions that eliminate and/or reduce the error chance for an error on both the abutted contact regions and the next contact region. An analysis is carried through where, for all input combinations of the inputs to the first cells and inputs to the second cell which do not come from the first cell, the result of an error to the first cell and an error to the second cell is examined for both outputs of the second cell (both the regular output and the complementary output). TABLE 4 illustrates one embodiment of an error analysis for two series connected LEAP^{R}NAND cells caused by an error in the first cell and an error in the second cell. The analysis is performed for all input combinations of a, b, and c, wherein a and b are inputs to the first cell and c is an input to the second cell that is not provided by the first cell.

TABLE 4

| LEAP^{R}NAND | | | | | | | | | | | | | | | |
|---|---|---|---|---|---|---|---|---|---|---|---|---|---|---|---|
| | | | | output | DIR | | | | | | | | | | |
| input | | | | NAND | NOR | 2^{nd} LEAP^{R}NAND | | | | SET | | SET | SET | | SET |
| a | b | ai | bi | Q=!(a&b) | Qi=!(ai\|bi) | c | ci | Q2 | Q2i | Q | Q2 | Q2 | Qi | Q2i | Q2i |
| 0 | 0 | 1 | 1 | 1 | 1 | 0 | 1 | 1 | 0 | 1−>0 | 1 | 1 | 0−>1 | 0 | 0 |
| 0 | 1 | 1 | 0 | 1 | 0 | 0 | 1 | 1 | 0 | 1−>0 | 1 | 1 | 0−>1 | 0 | 0 |
| 1 | 0 | 0 | 1 | 1 | 1 | 0 | 1 | 1 | 0 | 1−>0 | 1 | 1 | 0−>1 | 0 | 0 |
| 1 | 1 | 0 | 0 | 0 | 0 | 0 | 1 | 1 | 0 | 0−>1 | 1 | 1 | 1−>0 | 0 | 0 |
| 0 | 0 | 1 | 1 | 1 | 1 | 1 | 0 | 0 | 1 | 1−>0 | 1 | 0−>1 | 0−>1 | 0 | 1−>0 |
| 0 | 1 | 1 | 0 | 1 | 0 | 1 | 0 | 0 | 1 | 1−>0 | 1 | 0−>1 | 0−>1 | 0 | 1−>0 |
| 1 | 0 | 0 | 1 | 1 | 1 | 1 | 0 | 0 | 1 | 1−>0 | 1 | 0−>1 | 0−>1 | 0 | 1−>0 |
| 1 | 1 | 0 | 0 | 0 | 0 | 1 | 0 | 1 | 0 | 0−>1 | 0 | 1−>0 | 1−>0 | 1 | 0−>1 |

In one embodiment, the inputs of the first cell and the second cell comprise a=0, b=0, and c=0. The regular output of the first LEAP^{R}NAND gate, Q, is 1 for this input combination. An error will cause Q to change from 1 to 0. If this error occurs on Q, the error will not propagate to the output of the second LEAP^{R}NAND cell, Q2 due to logic filtering. Q2 will keep a value of 1. Similarly an error changing 0 to 1 on Qi (the inverse of Q) will not generate an error on Q2i. Therefore, in this state, an error in the first LEAP^{R}NAND cell and an error in the second LEAP^{R}NAND cell cannot cause an error on both outputs of the second LEAP^{R}NAND cell. In another embodiment, given an input combination of a=0, b=0, and c=1, an error may propagate to both outputs of the second cell. An error may cause Q to change from 1 to 0 in the first cell. This error will cause an error on Q2. The error on Q2 can combine with an error on Qi in the second cell, causing Q2i to transition from 1 to zero, which will result in an error on both outputs, Q2 and Q2i. TABLE 4 identifies the combination errors in Q and Q2 that may result in errors on both outputs of the second cell.

In some embodiments, each abutment possibility for the primary-to-primary and redundant-redundant contact area is analyzed by considering the contact areas closest to the abutment region, but belonging to another net, such as, for example, if a primary-to-primary abutment is analyzed the contact regions closest to the abutment region, but connected to the redundant net are considered. A combination of an error on one of the contact regions with an error on one of the abutting regions is evaluated. In the case of two LEAP^{R}NAND cells, three cases are possible for each of the basic primary-primary/redundant-redundant abutments: nmos-nmos, pmos-pmos, and nmos-pmos, which provides a total of six different abutment possibilities. All errors that can occur on an abutment region and the closest contact region belonging to the other net are considered, and the abutment that gives no errors (or the least error cases) is the preferred abutment.

In one embodiment, the effect of a single event on the first contact region and a single event on the next closest contact region of the opposite net is considered. In embodiments comprising bulk CMOS technology, a single event affecting an n-type contact region pulls the voltage low (1->0) while a single event for a p-type contact region pulls the voltage high (0->1). In embodiments comprising SOI CMOS technology, the effect of a single event shorts the MOSFET, as one of the drain/source contacts of a p-type MOSFET is connected to the high voltage (power, VDD) and one of the source/drain contacts of an n-type MOSFET is connected to a low voltage (ground, GND). For the LEAP^{R}NAND circuit bulk CMOS and SOI CMOS behavior is the same.

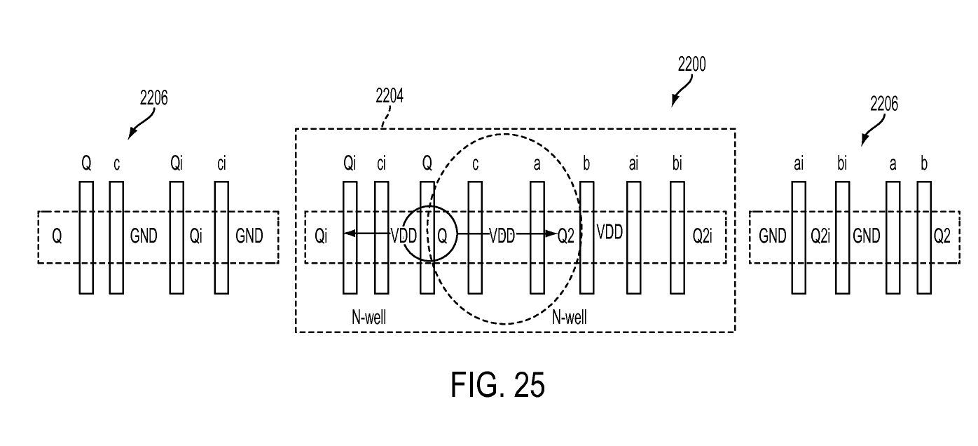

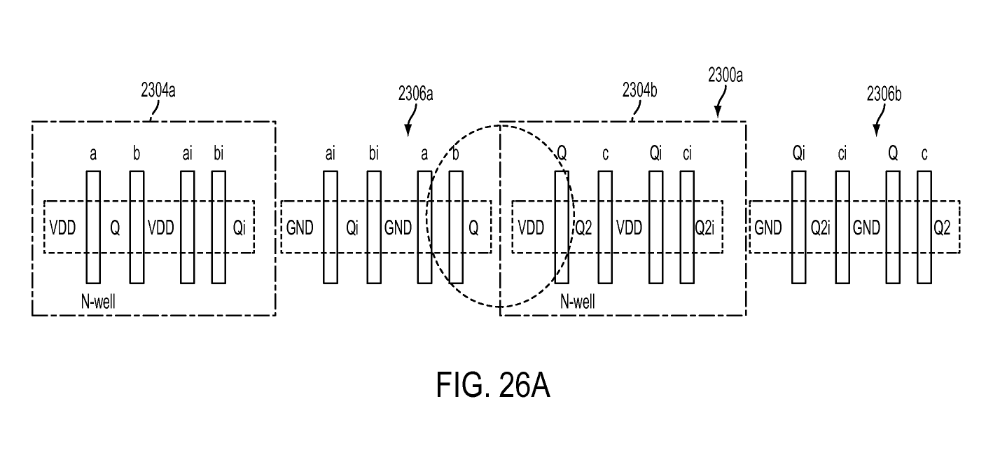

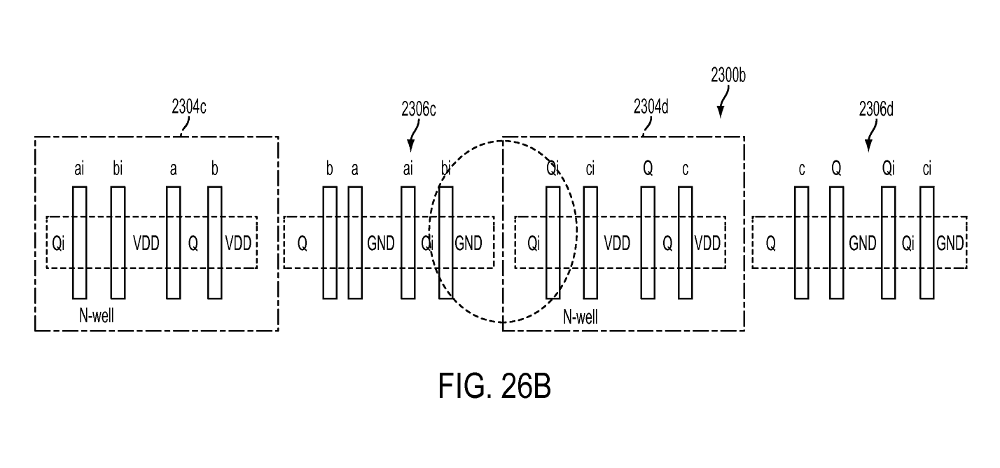

FIG. 25 illustrates one embodiment of a LEAP^{R}NAND gate abutment 2200. The abutment region and the adjacent contact region belonging to a different net are p-type contact regions. An error generated on the primary abutment region comprises a change from 0 to 1, and an error generated on the closest redundant contact region comprises a change from 0 to 1. The gate abutment 2200 comprises four error cases. FIGS. 26A and 26B illustrate LEAP^{R}NAND gate abutments 2300a, 2300b that eliminate errors caused by a single event in the primary net and a single event in the next closest contact region belonging to the redundant net. If the abutting regions in one cell are n-type and the contact regions in the next cell are p-type, there are no error cases even if the contact regions adjacent to the abutment regions and belonging to the other net are affected by the single event. Therefore, a LEAP^{R}NAND to LEAP^{R}NAND abutment should be nmos-pmos (either primary-primary or redundant-redundant). A similar analysis for the LEAP^{R}INV cell will yield the same result: abutments comprising primary-primary or redundant-redundant and nmos-pmos contact regions prevent errors caused by a single event in the abutment region and in the next contact region of the other net.

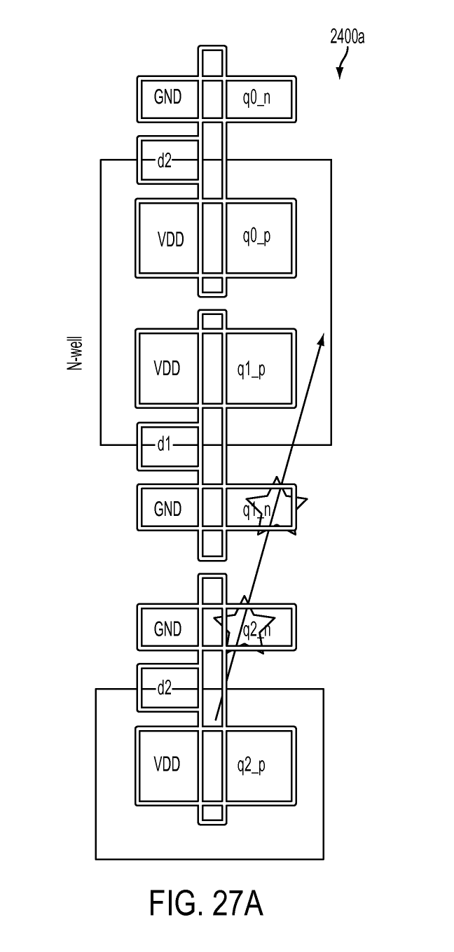

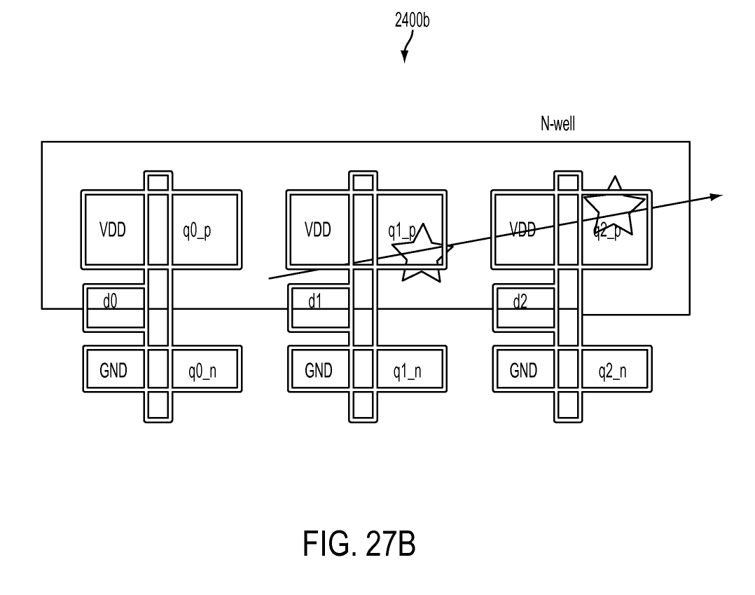

In some embodiments, a LEAP circuit may comprise triple mode redundancy (TMR). TMR refers to a triplication of logic such that three copies of the data are present in the circuit. Triple mode redundancy in logic circuits may be referred to as LEAP^{3R}. By performing a vote of the three copies of the data, the correct value can be retrieved even if one of the data paths has the wrong value. FIGS. 27A and 27B illustrate TMR inverter circuits 2400a, 2400b comprising three data paths each carrying a copy of the data. In an embodiment comprising a TMR inverter, consisting of three parallel inverter (INV) gates, if a single event affects any two of the n-drains (or any two of the p-drains), an error will be generated on two data paths, resulting in an error in the circuit.

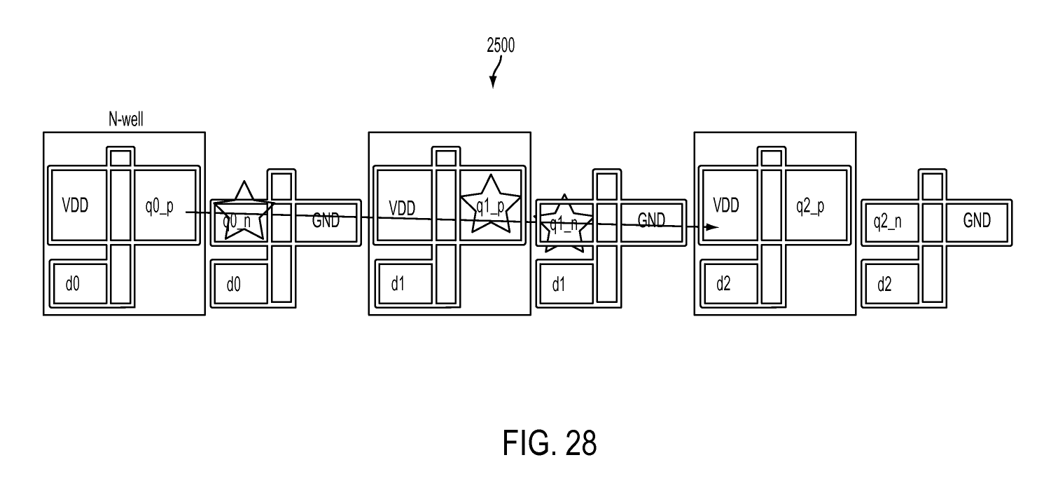

In some embodiments, the effect of single event errors on abutting contact regions are reduced by laying out the circuit according to the LEAP methodology. FIG. 28 illustrates one embodiment of a TMR inverter 2500 comprising a LEAP layout. A p-type drain is placed between the n-type drains to provide an opposing effect to the effect on the two n-type drains. The p-type drain provides a compensating effect, compared the inverter cells 2400a, 2400b illustrated in FIGS. 27A and 27B, and will reduce the probability that an error is generated on two n-drains (and vice versa). However, the p-type and n-type effects, while opposing each other, may be of different strength and the compensation is not optimal. Furthermore, the TMR inverter 2500 increases the complexity of the routing and increases the area of the circuit.

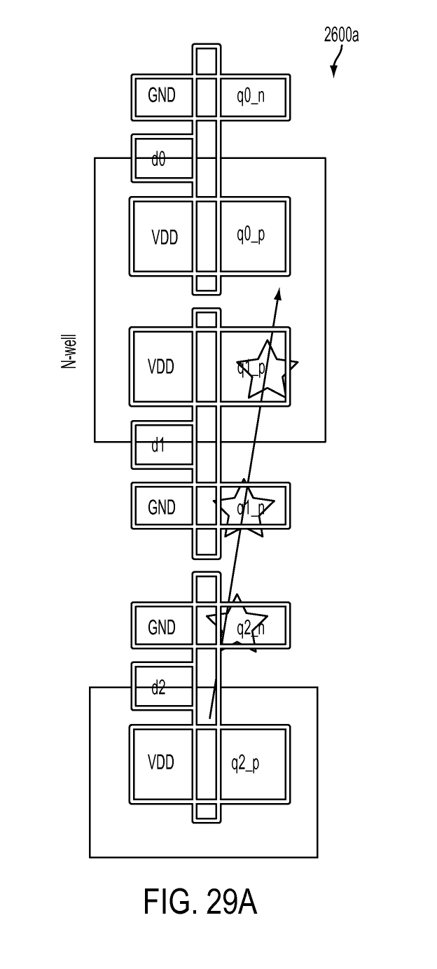

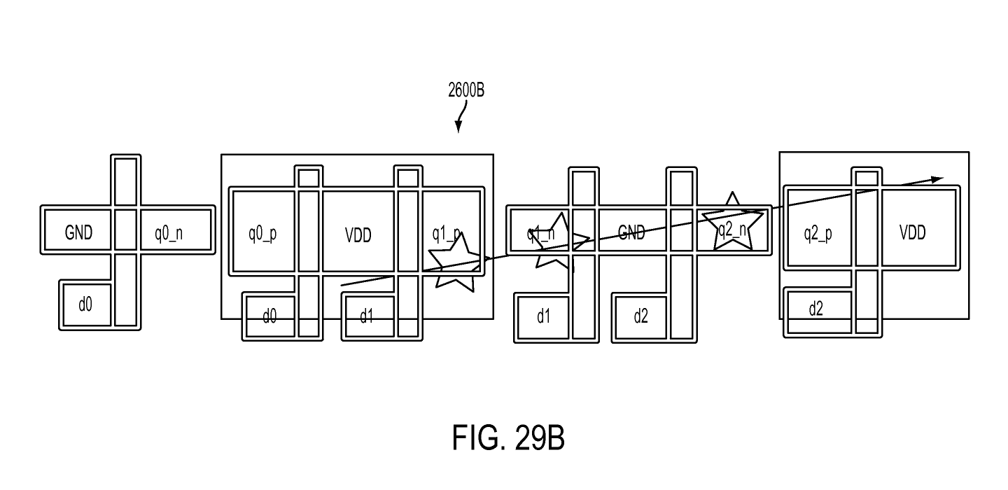

In some embodiments, the effect of a single event error on a TMR inverter is further reduced by configuring one of the three data paths to carry a complementary (inverse) value of the data. FIGS. 29A and 29B illustrate various embodiments of LEAR^{3R} TMR inverter cells 2600a, 2600b comprising an inverted data path. In one embodiment, the inverted data path is placed between the two paths that carry the data. For example, in the embodiments illustrated in FIGS. 29A and 29B, the inverted data path, path 1, is placed between the paths that carry the data, paths 0 and 2. When only n-drains are considered, an error can only be generated if the n-drains connected to paths 0 and 2 are affected. A single event on data path 0 and path 1 or path 1 and path 2 does not generate an error. Placing an inverse data logic cell between two logic cells carrying the data causes the n-drains of the logic circuits illustrated in FIGS. 29A and 29B to be further apart than the n-drains of the logic circuit illustrated in FIGS. 27A and 27B.

In the embodiments illustrated in FIGS. 29A and 29B, single events that affect drains of opposite types (n or p) in logic paths 1 and 0 or paths 1 and 2 will generate errors, compared to the embodiments illustrated in FIGS. 27A and 27B in which a single event that affects the drains of opposite type in logic paths 1 and 0 or logic paths 1 and 2 does not generate an error. However, opposite-type, multiple node errors can be compensated more efficiently in cases where the strength of the single event effect on n-type and p-type contact regions are different. For example, if the single event effect on an n-type drain is stronger than on a p-type drain, for example in bulk CMOS, then an uncompensated error on the n-type drain will occur, but the single event effect on the p-type drain will be efficiently compensated. Therefore, the probability of generating an error on one n-type and one p-type drain can be compensated much more efficiently than an error on two n-type drains.

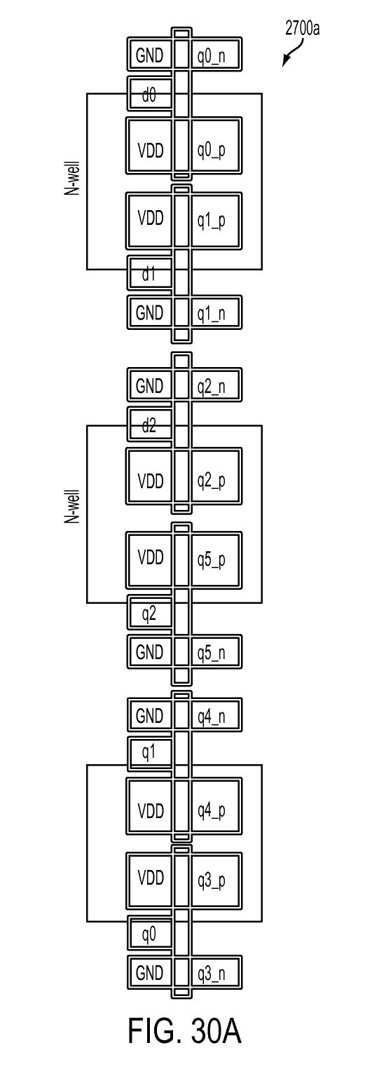

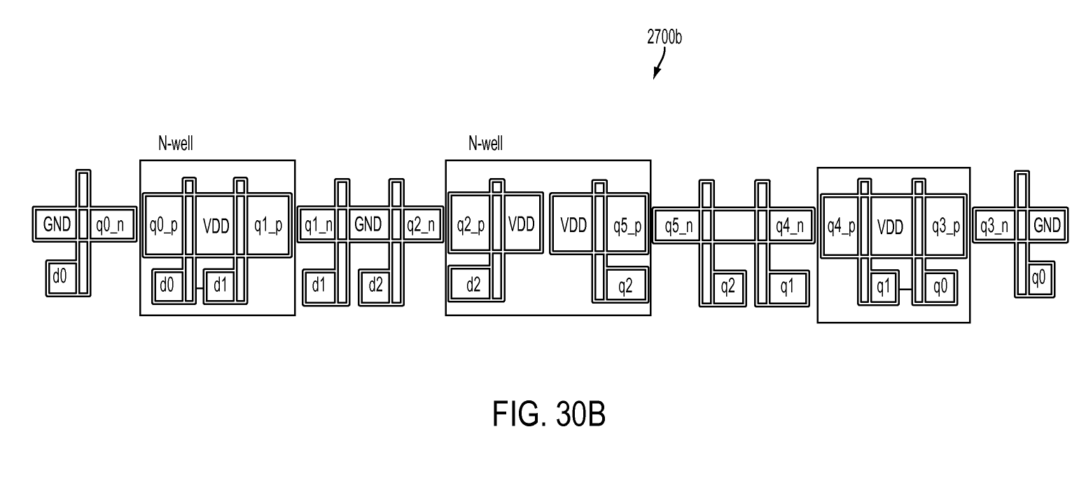

FIGS. 30A and 30B illustrate various embodiments of a TMR inverter circuits 2700a, 2700b comprising an inverse data path in the middle logic circuit and compensating nodes between the contact pairs of two data paths. The contact pairs comprising two n-type (or two p-type) drains have several compensating contact areas therebetween. By carrying the inverse of the data on the middle path, the TMR inverter circuits have one or more compensating contact areas between any two nodes which can generate errors on two data paths. The methodology discussed above may also be applied to inter-cell placement of two or more connected LEAP^{3R} logic cells For example, in one embodiment, if two INV cells, configured with triple mode redundancy and an inverse data path, are connected in a circuit, the two INV cells are placed such that R-direction along which their contact nodes have been placed coincides and that the nets in the abutment regions in the first and second cell belong to the same data path.

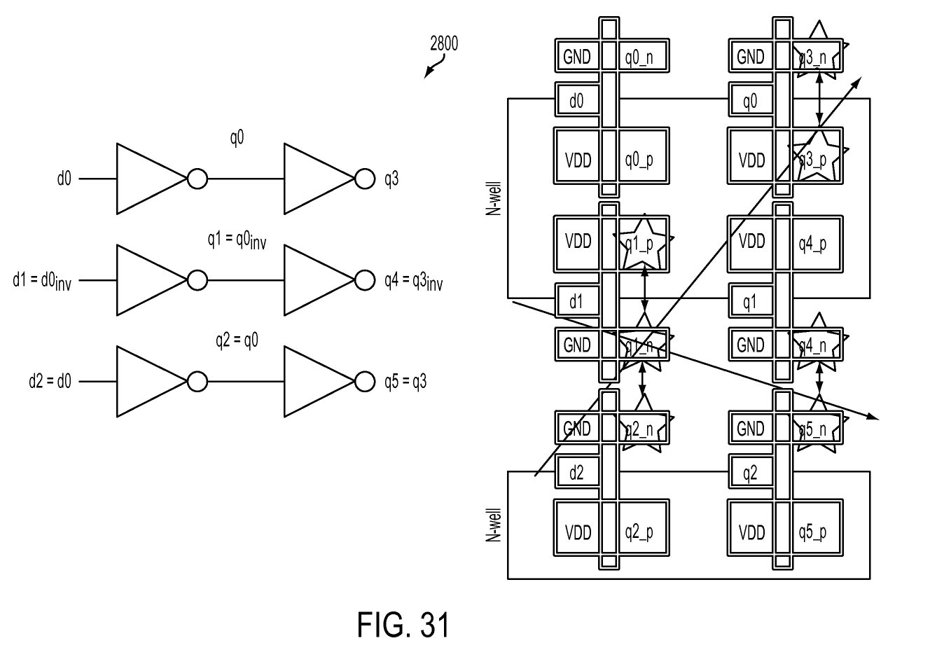

In some embodiments, inter-cell placement that does not strictly comply with the methodology discussed above for a TMR LEAP^{3R} cell will still be much harder than the regular TMR design. FIG. 31 illustrates one embodiment of a LEAP circuit 2800 comprising two TMR INV cells placed along different R-directions. In the illustrated embodiment, several opposing contact regions are close to the line between two contact regions that can generate an error on two different data paths, one in the first cell and one in the second cell. The inter-cell placement of the INV cells avoids direct abutment of a contact region in the first cell which can generate an error on one net in the first cell and a contact region in the second cell which can generate an error on another data path in the second cell.

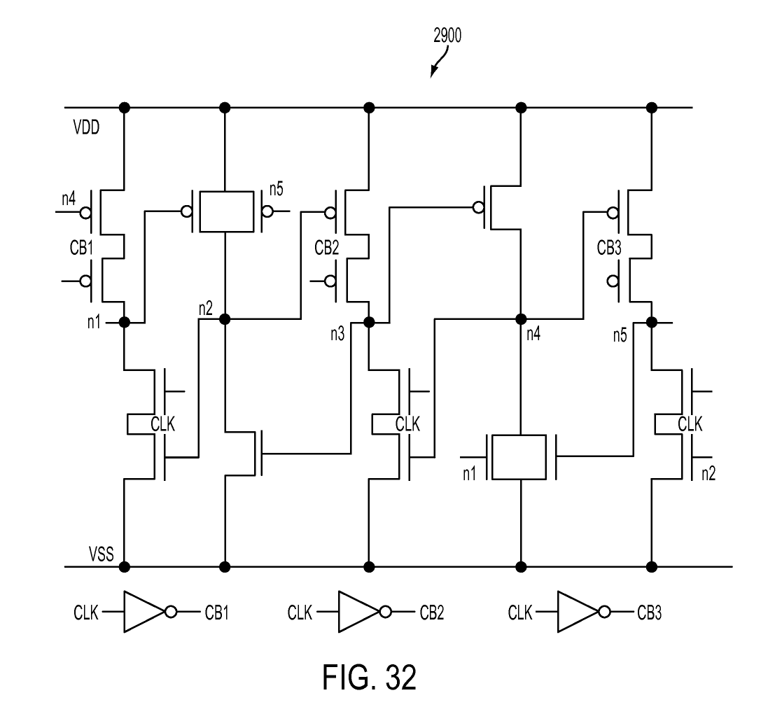

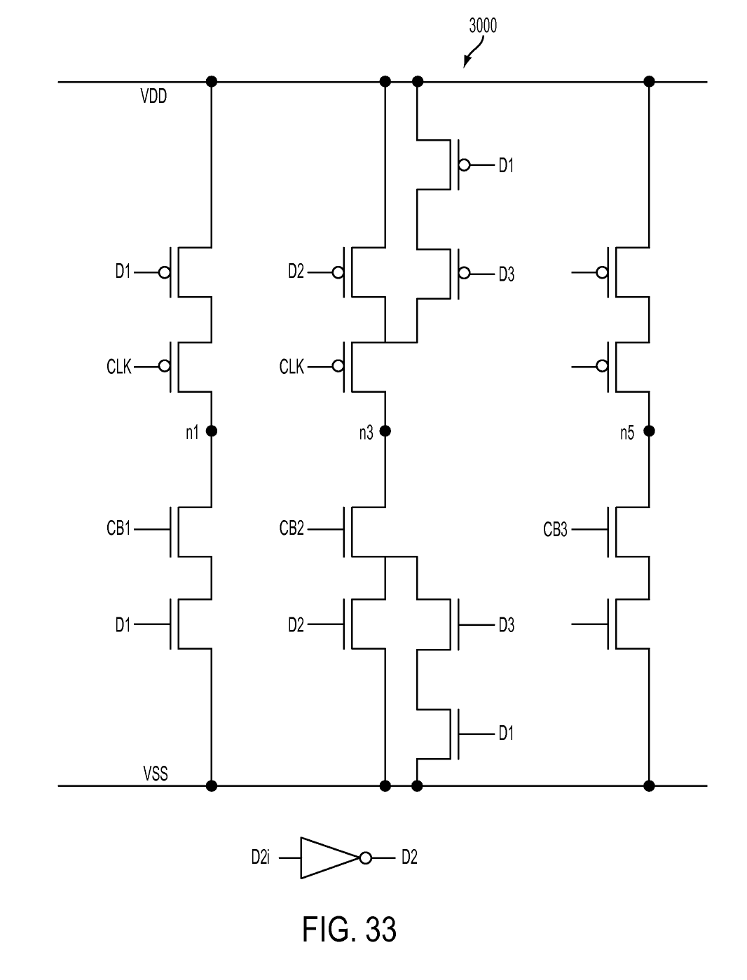

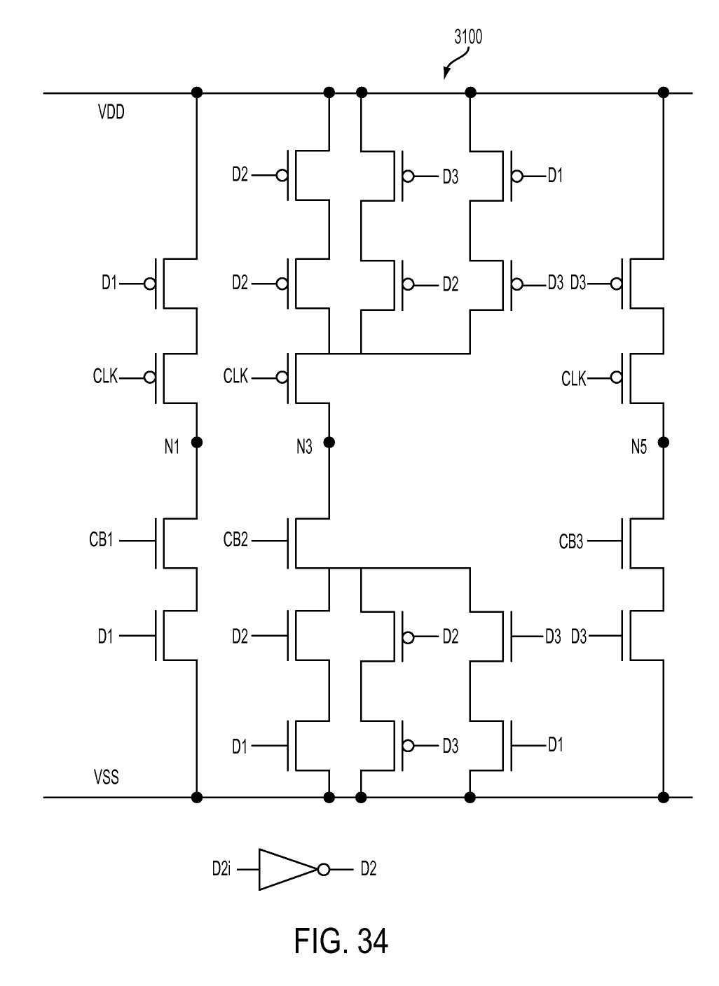

In the illustrated embodiments comprising LEAP^{3R} inverter cells having a data path carrying the inverse of the data, a modified voter cell is used. In one embodiment, data in the inverse data path is inverted before the three data path signals are fed into a regular voter. In another embodiment, a LEAPVOTER is used. FIGS. 32-34 illustrate various embodiments of a LEAPVOTER 2900. FIG. 33 illustrates a partial voting input path 3000. FIG. 34 illustrates a full voting input path 3100. The partial voting input path 3000 and/or the full voting input path 3100 may be connected to the center clocking branch of the LEAPVOTER circuit 2900. In another embodiment, a partial voting path similar to the partial voting path 3000 illustrated in FIG. 33, but with the series p-type MOSFETS and n-type MOSFETS connected to D1 and D3 removed, is used and will vote correctly if an error pulse occurs on one of the three inputs. However, if a permanent error occurs on D2, the clocking circuit will not vote correctly under all circumstances.

Various embodiments may be described herein in the general context of computer executable instructions, such as software, program modules, and/or engines being executed by a computer. Generally, software, program modules, and/or engines include any software element arranged to perform particular operations or implement particular abstract data types. Software, program modules, and/or engines can include routines, programs, objects, components, data structures and the like that perform particular tasks or implement particular abstract data types. An implementation of the software, program modules, and/or engines components and techniques may be stored on and/or transmitted across some form of computer-readable media. In this regard, computer-readable media can be any available medium or media useable to store information and accessible by a computing device. Some embodiments also may be practiced in distributed computing environments where operations are performed by one or more remote processing devices that are linked through a communications network. In a distributed computing environment, software, program modules, and/or engines may be located in both local and remote computer storage media including memory storage devices.

Although some embodiments may be illustrated and described as comprising functional components, software, engines, and/or modules performing various operations, it can be appreciated that such components or modules may be implemented by one or more hardware components, software components, and/or combination thereof. The functional components, software, engines, and/or modules may be implemented, for example, by logic (e.g., instructions, data, and/or code) to be executed by a logic device (e.g., processor). Such logic may be stored internally or externally to a logic device on one or more types of computer-readable storage media. In other embodiments, the functional components such as software, engines, and/or modules may be implemented by hardware elements that may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Examples of software, engines, and/or modules may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

In some cases, various embodiments may be implemented as an article of manufacture. The article of manufacture may include a computer readable storage medium arranged to store logic, instructions and/or data for performing various operations of one or more embodiments. In various embodiments, for example, the article of manufacture may comprise a magnetic disk, optical disk, flash memory or firmware containing computer program instructions suitable for execution by a general purpose processor or application specific processor. The embodiments, however, are not limited in this context.

While various details have been set forth in the foregoing description, it will be appreciated that the various embodiments of the apparatus, system, and method for circuit and layout design for soft-error hard integrated circuits may be practiced without these specific details. For example, for conciseness and clarity selected aspects have been shown in block diagram form rather than in detail. Some portions of the detailed descriptions provided herein may be presented in terms of instructions that operate on data that is stored in a computer memory. Such descriptions and representations are used by those skilled in the art to describe and convey the substance of their work to others skilled in the art. In general, an algorithm refers to a self-consistent sequence of steps leading to a desired result, where a “step” refers to a manipulation of physical quantities which may, though need not necessarily, take the form of electrical or magnetic signals capable of being stored, transferred, combined, compared, and otherwise manipulated. It is common usage to refer to these signals as bits, values, elements, symbols, characters, terms, numbers, or the like. These and similar terms may be associated with the appropriate physical quantities and are merely convenient labels applied to these quantities.

Unless specifically stated otherwise as apparent from the foregoing discussion, it is appreciated that, throughout the foregoing description, discussions using terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

It is worthy to note that any reference to “one aspect,” “an aspect,” “one embodiment,” or “an embodiment” means that a particular feature, structure, or characteristic described in connection with the aspect is included in at least one aspect. Thus, appearances of the phrases “in one aspect,” “in an aspect,” “in one embodiment,” or “in an embodiment” in various places throughout the specification are not necessarily all referring to the same aspect. Furthermore, the particular features, structures or characteristics may be combined in any suitable manner in one or more aspects.

Although various embodiments have been described herein, many modifications, variations, substitutions, changes, and equivalents to those embodiments may be implemented and will occur to those skilled in the art. Also, where materials are disclosed for certain components, other materials may be used. It is therefore to be understood that the foregoing description and the appended claims are intended to cover all such modifications and variations as falling within the scope of the disclosed embodiments. The following claims are intended to cover all such modification and variations.

In summary, numerous benefits have been described which result from employing the concepts described herein. The foregoing description of the one or more embodiments has been presented for purposes of illustration and description. It is not intended to be exhaustive or limiting to the precise form disclosed. Modifications or variations are possible in light of the above teachings. The one or more embodiments were chosen and described in order to illustrate principles and practical application to thereby enable one of ordinary skill in the art to utilize the various embodiments and with various modifications as are suited to the particular use contemplated. It is intended that the claims submitted herewith define the overall scope.

Some or all of the embodiments described herein may generally comprise technologies which can be implemented, individually, and/or collectively, by a wide range of hardware, software, firmware, or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link (e.g., transmitter, receiver, transmission logic, reception logic, etc.), etc.).

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken limiting.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, different other components. It is to be understood that such depicted architectures are merely exemplary, and that in fact many other architectures may be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components, and/or wirelessly interactable, and/or wirelessly interacting components, and/or logically interacting, and/or logically interactable components.

In some instances, one or more components may be referred to herein as “configured to,” “configurable to,” “operable/operative to,” “adapted/adaptable,” “able to,” “conformable/conformed to,” etc. Those skilled in the art will recognize that “configured to” can generally encompass active-state components and/or inactive-state components and/or standby-state components, unless context requires otherwise.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although various operational flows are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

Those skilled in the art will recognize that it is common within the art to implement devices and/or processes and/or systems, and thereafter use engineering and/or other practices to integrate such implemented devices and/or processes and/or systems into more comprehensive devices and/or processes and/or systems. That is, at least a portion of the devices and/or processes and/or systems described herein can be integrated into other devices and/or processes and/or systems via a reasonable amount of experimentation. Those having skill in the art will recognize that examples of such other devices and/or processes and/or systems might include—as appropriate to context and application—all or part of devices and/or processes and/or systems of (a) an air conveyance (e.g., an airplane, rocket, helicopter, etc.), (b) a ground conveyance (e.g., a car, truck, locomotive, tank, armored personnel carrier, etc.), (c) a building (e.g., a home, warehouse, office, etc.), (d) an appliance (e.g., a refrigerator, a washing machine, a dryer, etc.), (e) a communications system (e.g., a networked system, a telephone system, a Voice over IP system, etc.), (f) a business entity (e.g., an Internet Service Provider (ISP) entity such as Comcast Cable, Qwest, Southwestern Bell, etc.), or (g) a wired/wireless services entity (e.g., Sprint, Cingular, Nextel, etc.), etc.

In certain cases, use of a system or method may occur in a territory even if components are located outside the territory. For example, in a distributed computing context, use of a distributed computing system may occur in a territory even though parts of the system may be located outside of the territory (e.g., relay, server, processor, signal-bearing medium, transmitting computer, receiving computer, etc. located outside the territory).

A sale of a system or method may likewise occur in a territory even if components of the system or method are located and/or used outside the territory. Further, implementation of at least part of a system for performing a method in one territory does not preclude use of the system in another territory.

In summary, numerous benefits have been described which result from employing the concepts described herein. The foregoing description of the one or more embodiments has been presented for purposes of illustration and description. It is not intended to be exhaustive or limiting to the precise form disclosed. Modifications or variations are possible in light of the above teachings. The one or more embodiments were chosen and described in order to illustrate principles and practical application to thereby enable one of ordinary skill in the art to utilize the various embodiments and with various modifications as are suited to the particular use contemplated. It is intended that the claims submitted herewith define the overall scope.

Various aspects of the subject matter described herein are set out in the following numbered clauses:

What is claimed is:

1. An integrated circuit comprising logic cells with one or more sets of two complementary inputs and one or more sets of two complementary outputs, the integrated circuit derived from an integrated circuit layout comprising:
a first contact area from a first logic cell;
a second contact area from a second logic cell comprising a non-zero, non-opposing effect with respect to the first contact area, wherein the first contact area and the second contact area comprise a first distance, and
wherein:
when the first distance is below a predetermined threshold, the first logic cell and the second logic cell are placed along a first R-line of the integrated circuit such that a third contact area, from either of the first or second logic cells, comprising an opposing effect with respect to the first contact area and the second contact area, is placed between the first contact area and second contact area; and
when the first distance is not below the predetermined threshold:
a filter cell is inserted between the first contact area and the second contact area, the filter cell configured to decouple the first logic cell and the second logic cells; and
the first contact area is placed along the first R-line and the second contact area is placed along a second R-line of the integrated circuit.

2. The integrated circuit of claim 1, wherein the filter cell is placed at least partially along the second R-line when the first distance is not below the predetermined threshold.

3. The integrated circuit of claim 2, wherein the filter cell comprises a first circuit path comprising one or more contact areas placed along the first R-line and a second circuit path placed along the second R-line.

4. The integrated circuit of claim 1, wherein the filter cell comprises:
a first p-type MOSFET comprising a first source coupled to a power net, a first drain, and a first gate coupled to an input;
a second p-type MOSFET comprising a second source coupled to the first drain of the first p-type MOSFET, a second drain coupled to an inverse output, and a second gate coupled to an inverse of a complementary signal of the input;
a third p-type MOSFET comprising a third source coupled to the power net, a third drain, and a third gate coupled to the complementary signal of the input;
a fourth p-type MOSFET comprising a fourth source coupled to the third drain of the third p-type MOSFET, a fourth drain coupled to an output, and a fourth gate coupled to an inverse of the input;
a first n-type MOSFET comprising a fifth source coupled to a ground net, a fifth drain, and a fifth gate coupled to the input;
a second n-type MOSFET comprising a sixth source coupled to the fifth drain of the first n-type MOSFET, a sixth drain coupled to the inverse output, and a sixth gate coupled to the inverse of the complementary signal of the input;
a third n-type MOSFET comprising a seventh source coupled to the ground net, a seventh drain, and a seventh gate coupled to the complementary signal of the first input; and
a fourth n-type MOSFET comprising an eighth source coupled to the seventh drain of the third n-type MOSFET, an eighth drain coupled to the output, and an eighth gate coupled to the inverse of the input.

5. A method of designing an integrated circuit comprising logic cells with one or more sets of two complementary inputs and one or more sets of two complementary outputs, the integrated circuit derived from an integrated circuit layout, the method comprising:
accessing in the integrated circuit layout, by a processor, a first contact area from a first logic cell;
accessing in the integrated circuit layout, by the processor, a second contact area from a second logic cell comprising a non-zero, non-opposing effect with respect to the first contact area;
determining, by the processor, a first distance between the first contact area and the second contact area;
determining, by the processor, whether the first distance is below a predetermined threshold;
when it is determined the first distance is below the predetermined threshold:
placing in the integrated circuit layout, by the processor, the first logic cell and the second logic cell along a first R-line of the integrated circuit; and
placing in the integrated circuit layout, by the processor, a third contact area, from either of the first or second logic cells, comprising an opposing effect with respect to the first contact area and the second contact area, such that the third contact area is placed between the first contact area and second contact area; and
when it is determined that the first distance is not below the predetermined threshold:
inserting in the integrated circuit layout, by the processor, a filter cell between the first contact area and the second contact area, the filter cell configured to decouple the first logic cell and the second logic cells;
placing in the integrated circuit layout, by the processor, the first contact area along the first R-line; and
placing in the integrated circuit layout, by the processor, the second contact area along a second R-line of the integrated circuit.

6. The method of claim 5, further comprising placing the filter cell at least partially along the second R-line when it is determined the first distance is not below the predetermined threshold.

7. The method of claim 6, wherein the filter cell comprises a first circuit path comprising one or more contact areas placed along the first R-line and a second circuit path placed along the second R-line.

8. The method of claim 5, wherein the filter cell comprises:
a first p-type MOSFET comprising a first source coupled to a power net, a first drain, and a first gate coupled to an input;
a second p-type MOSFET comprising a second source coupled to the first drain of the first p-type MOSFET, a second drain coupled to an inverse output, and a second gate coupled to an inverse of a complementary signal of the input;
a third p-type MOSFET comprising a third source coupled to the power net, a third drain, and a third gate coupled to the complementary signal of the input;
a fourth p-type MOSFET comprising a fourth source coupled to the third drain of the third p-type MOSFET, a fourth drain coupled to an output, and a fourth gate coupled to an inverse of the input;
a first n-type MOSFET comprising a fifth source coupled to a ground net, a fifth drain, and a fifth gate coupled to the input;
a second n-type MOSFET comprising a sixth source coupled to the fifth drain of the first n-type MOSFET, a sixth drain coupled to the inverse output, and a sixth gate coupled to the inverse of the complementary signal of the input;
a third n-type MOSFET comprising a seventh source coupled to the ground net, a seventh drain, and a seventh gate coupled to the complementary signal of the first input; and
a fourth n-type MOSFET comprising an eighth source coupled to the seventh drain of the third n-type MOSFET, an eighth drain coupled to the output, and an eighth gate coupled to the inverse of the input.

9. A non-transitory computer readable medium comprising instructions that, when executed by a processor, cause a machine to perform operations comprising:
accessing in an integrated circuit layout a first contact area from a first logic cell;
accessing in the integrated circuit layout a second contact area from a second logic cell comprising a non-zero, non-opposing effect with respect to the first contact area;
determining a first distance between the first contact area and the second contact area;
determining whether the first distance is below a predetermined threshold;
when it is determined the first distance is below the predetermined threshold:
placing in the integrated circuit layout the first logic cell and the second logic cell along a first R-line of the integrated circuit; and
placing in the integrated circuit layout a third contact area, from either of the first or second logic cells, comprising an opposing effect with respect to the first contact area and the second contact area, such that the third contact area is placed between the first contact area and second contact area; and
when it is determined that the first distance is not below the predetermined threshold:
inserting in the integrated circuit layou a filter cell between the first contact area and the second contact area, the filter cell configured to decouple the first logic cell and the second logic cells;
placing in the integrated circuit layout the first contact area along the first R-line; and
placing in the integrated circuit layout the second contact area along a second R-line of the integrated circuit.

10. The computer readable medium of claim 9, wherein the operations further comprise placing the filter cell at least partially along the second R-line when it is determined the first distance is not below the predetermined threshold.

11. The computer readable medium of claim 10, wherein the filter cell comprises a first circuit path comprising one or more contact areas placed along the first R-line and a second circuit path placed along the second R-line.

12. The computer readable medium of claim 9, wherein the filter cell comprises:
a first p-type MOSFET comprising a first source coupled to a power net, a first drain, and a first gate coupled to an input;
a second p-type MOSFET comprising a second source coupled to the first drain of the first p-type MOSFET, a second drain coupled to an inverse output, and a second gate coupled to an inverse of a complementary signal of the input;
a third p-type MOSFET comprising a third source coupled to the power net, a third drain, and a third gate coupled to the complementary signal of the input;
a fourth p-type MOSFET comprising a fourth source coupled to the third drain of the third p-type MOSFET, a fourth drain coupled to an output, and a fourth gate coupled to an inverse of the input;
a first n-type MOSFET comprising a fifth source coupled to a ground net, a fifth drain, and a fifth gate coupled to the input;
a second n-type MOSFET comprising a sixth source coupled to the fifth drain of the first n-type MOSFET, a sixth drain coupled to the inverse output, and a sixth gate coupled to the inverse of the complementary signal of the input;
a third n-type MOSFET comprising a seventh source coupled to the ground net, a seventh drain, and a seventh gate coupled to the complementary signal of the first input; and
a fourth n-type MOSFET comprising an eighth source coupled to the seventh drain of the third n-type MOSFET, an eighth drain coupled to the output, and an eighth gate coupled to the inverse of the input.
